(19) United States
(12) Patent Application Publication
(10) Pub. No.: US 2011/0262863 A1
(43) Pub. Date: Oct. 27, 2011

(54) NEAR-INFRARED ABSORPTIVE LAYER-FORMING COMPOSITION AND MULTILAYER FILM

(76) Inventors: Seiichiro TACHIBANA, Joetsu-shi (JP); Masaki Ohashi, Joetsu-shi (JP); Kazumi Noda, Joetsu-shi (JP); Shozo Shirai, Joetsu-shi (JP); Takeshi Kinsho, Joetsu-shi (JP); Wu-Song Huang, Hopewell Junction, NY (US); Dario L. Goldfarb, Yorktown Heights, NY (US); Wai-Kin Li, Hopewell Junction, NY (US); Martin Glodde, Hopewell Junction, NY (US)

(21) Appl. No.: 13/091,290

(22) Filed: Apr. 21, 2011

(30) Foreign Application Priority Data
Apr. 22, 2010 (JP) 2010-098453
Mar. 4, 2011 (JP) 2011-047254

(51) Int. Cl. G03F 7/004; F21V 9/04

(52) U.S. Cl. 430/272.1; 252/587; 430/271.1

(57) ABSTRACT

A near-infrared absorptive layer is formed from a composition comprising (A) an acenaphthylene polymer, (B) a near-infrared absorbing dye, and (C) a solvent. When a multilayer film comprising the near-infrared absorptive layer and a photoresist layer is used in optical lithography, the detection accuracy of optical auto-focusing is improved, allowing the optical lithography to produce a definite projection image with an improved contrast and succeeding in forming a better photoresist pattern.

### CROSS-REFERENCE TO RELATED APPLICATION

This non-provisional application claims priority under 35 U.S.C. §119(a) on Patent Application Nos. 2010-098453 and 2011-047254 filed in Japan on Apr. 22, 2010 and Mar. 4, 2011, respectively, the entire contents of which are hereby incorporated by reference.

### TECHNICAL FIELD

This invention relates to a near-infrared absorptive layer-forming composition for use in microfabrication in the semiconductor device manufacture process, and more particularly, to a near-infrared absorptive layer-forming composition adapted for exposure to ArF excimer laser radiation (193 nm). It also relates to a multilayer film formed using the composition.

### BACKGROUND ART

Semiconductor devices are manufactured by the microfabrication technology based on photolithography. In the photolithography, a photoresist layer is formed on a silicon wafer. Using an exposure apparatus, an image on an original plate known as a reticle or mask is transferred to the photoresist layer, which is developed into a resist pattern. Then the silicon or a metal or another material underneath the resist pattern is etched for forming an electronic circuit on the silicon wafer. In order to form a pattern of finer size for further integration of semiconductor devices, efforts have been made to reduce the wavelength of the exposure light used in the photolithography. In the mass production process of 64 Mbit DRAM, for example, KrF excimer laser (248 nm) is utilized. For the fabrication of DRAMs requiring a finer patterning size of 0.13 μm or less, ArF excimer laser (193 nm) is utilized. It is under investigation to fabricate 65-nm node devices by combining light of such shorter wavelength with a lens having an increased NA of 0.9. For the fabrication of next generation 45-nm node devices, the F₂ lithography of 157 nm wavelength became a candidate. However, for the reasons that the projection lens uses a large amount of expensive CaF₂ single crystal, the scanner thus becomes expensive, hard pellicles are adopted due to the extremely low durability of soft pellicles, the optical system must be accordingly altered, and the etch resistance of resist is low; the development of F₂ lithography is abandoned, and the ArF immersion lithography is now under study.

In the photolithography wherein a photoresist layer is exposed through a reticle, the moving stage on which a wafer rests is finely moved in the exposure apparatus in a projection light axis direction, so that the wafer surface may be in register with the best image plane of the projection optical system, that is, so as to enhance focus. Used as a sensor for such focusing is an optical focus detection system of the off-axis illumination type in which an imaging light flux (of non-exposure wavelength) is obliquely projected onto the wafer surface and the reflected light is detected, as disclosed in JP-A S58-113706. The imaging light flux used for this purpose is infrared light, especially near-infrared light, as disclosed in JP-A H02-54103, JP-A H06-29186, JP-A H07-146551, and US 20090208865.

The exposure apparatus using infrared light in the focus detection system suffers from the problem that an exact focus cannot be detected because infrared light is transmitted by a photoresist layer. That is, part of infrared light for focus detection is transmitted by the photoresist layer, the transmitted light is reflected by the substrate surface and enters the detection system along with the light reflected by the wafer top surface. As a result, the accuracy of focus detection is degraded.

The optical auto-focusing is such that the position of the top surface of the wafer is determined by reflecting infrared light on the wafer top surface and detecting the reflected light, after which the wafer is driven so as to fall in register with the imaging plane of the projection lens. Apart from the light reflected by the wafer top surface, there is present light that is transmitted by the resist layer and reflected by the substrate surface. If detection light having a certain band of light intensity distribution enters the detection system, the position measurement value represents the center of the light intensity distribution, leading to the degraded accuracy of focus detection. In general, the substrate has a multilayer structure including patterned metal, dielectric material, insulating material, ceramic material and the like, and the patterned substrate makes reflection of infrared light complex so that focus detection may be difficult. If the accuracy of focus detection is degraded, the projected image becomes vague to detract from the contrast, failing to form a satisfactory photoresist pattern.

To increase the accuracy of optical auto-focusing near infrared light, JP-A H07-146551 proposes the use of a photoresist layer containing a near-infrared absorbing dye. In this case, near-infrared light is not transmitted by the photoresist layer, and no reflected light other than the light reflected by the wafer top surface enters the focus detecting system, and as a result, the accuracy of focus detection is improved. However, since the near-infrared absorbing dye used therein should not be one that absorbs exposure light or degrades the resolution of a photoresist, it is least amenable to the photolithography using ArF excimer laser. US 20090208865 proposes a method for introducing a near-infrared absorbing dye-containing layer below a photoresist layer, which method can prevent degradation of the resolution of the resist.

One alternative to the optical autofocus technique is a method based on the principle that detects the pressure of air discharged onto the wafer surface, known as Air Gauge Improved Leveling (AGILE™). See Proc. of SPIE Vol. 5754, p. 681 (2005). Albeit excellent accuracy of position measurement, this method takes a long time for measurement and is not accepted in the mass production of semiconductor devices requiring improved throughputs.

It would be desirable to have a method capable of brief accurate auto-focusing in optical lithography.

### CITATION LIST

Patent Document 1: JP-A S58-113706
Patent Document 2: JP-A H02-54103
Patent Document 3: JP-A H06-29186
Patent Document 4: JP-A H07-146551
Patent Document 5: US 20090208865
Non-Patent Document 1: Proc. of SPIE Vol. 5754, p. 681 (2005)

### DISCLOSURE OF INVENTION

An object of the invention is to provide a material for forming a near-infrared absorptive layer used in optical auto-focusing for enabling high accuracy auto-focusing during optical lithography used in semiconductor microfabrication. Another object is to provide a multilayer film comprising a near-infrared absorptive layer of the near-infrared absorptive layer-forming material and a photoresist layer.

The inventors first studied a method of introducing a near-infrared (NIR) absorptive layer underneath a photoresist layer in order to enable high accuracy optical auto-focusing. It is believed that the introduction of a NIR absorptive layer prevents NIR light from being reflected from the substrate and entering a focus detection system, thus improving the accuracy of focus detection. It is also believed that this method is fully acceptable in commercial application because the optical focus detection system commonly used in the current semiconductor manufacturing plant can be used without modification, and the time taken for focus detection is as in the prior art.

In order to introduce a NIR absorptive layer, the inventors then attempted to additionally endow the existing antireflective coating for exposure light with a NIR absorption function so that the currently commercially applied wafer multilayer stacking process may be used without modification. One current approach is a trilayer process that uses a trilayer structure including a resist layer, a silicon-containing layer underneath the resist layer, and an underlayer having a high carbon density and high etch resistance, known as organic planarization layer (OPL), underneath the silicon-containing layer wherein the substrate may be processed utilizing an etching selective ratio between the layers and the reflection of exposure light may be prevented by adjusting optical properties of the layers, as disclosed in JP-A 2005-250434, JP-A 2007-171895, and JP-A 2008-65303. The inventors reached a concept to additionally endow the OPL with a NIR absorption function.

The base resin of OPL should have high etch resistance as well as sufficient optical properties to prevent reflection of exposure light. Also the resin used must undergo crosslinking reaction under the action of acid or heat so that the OPL may be fully cured since the OPL should not be impaired upon subsequent deposition of the silicon-containing layer.

JP-A H06-84789, JP-A 2005-15532, and JP-A 2005-250434 teach polymers obtained from copolymerization of acenaphthylene or derivatives thereof which are used as the base resin in antireflective coatings and underlayers. With these teachings borne in mind, the inventors attempted to form a NIR absorbing dye-containing layer using a polymer comprising repeat units of the general formula (1) as the base resin.

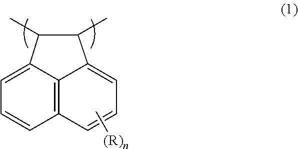

Herein R is hydrogen, a hydroxyl, carboxyl, hydroxymethyl, C₁-C₁₀ alkoxy, alkoxycarbonyl or C₁-C₁₀ acyloxy group, or a straight, branched or cyclic C₁-C₁₀ monovalent hydrocarbon group in which some hydrogen atoms may be substituted by halogen atoms and in which a —CH₂— moiety may be replaced by —O— or —C(═O)—, and n is an integer of 1 to 5. A polymer comprising repeat units of formula (1) displays high etch resistance since it has an aromatic ring (naphthalene structure) and its backbone has a ring structure incorporated therein. Further, since the refractive index (n value) and extinction coefficient (k value) of naphthalene at 193 nm are low, the polymer exhibits advantageous optical properties in terms of antireflection when used as OPL. That is, even when a notable amount of repeat units of formula (1) is incorporated in order to improve etch resistance, the polymer meets the optical properties necessary for antireflection at an ordinary OPL thickness. This is in stark contrast with a comparative example of styrene which is commonly used as a typical aromatic ring-containing monomer, wherein increasing a ratio of styrene-derived repeat units incorporated leads to an increased k value, failing in effective anti-reflection.

FIG. 1 is a diagram showing reflectivity versus Si-containing layer thickness measured for a multilayer film of ArF photoresist layer/Si-containing layer/OPL on a silicon wafer wherein the OPL is based on Polymer 1 comprising repeat units of formula (1) (shown in Example) as a base resin. FIG. 2 is a diagram showing reflectivity versus Si-containing layer thickness measured for a similar structure wherein the OPL is based on Polymer 5 comprising repeat units derived from styrene (also shown in Example) as a base resin. A comparison of FIGS. 1 and 2 reveals that OPL based on Polymer 1 provides a lower reflectivity in the Si-containing layer thickness range of 30 to 40 nm.

Based on these investigations, the inventors prepared a NIR absorptive layer-forming composition comprising (A) a polymer comprising repeat units having formula (1), (B) a near-infrared absorbing dye, and (C) a solvent and applied it onto a wafer. The thus formed layer has been found to display high etch resistance, exhibit proper optical properties to prevent reflection of exposure light of 193 nm when combined with the existing silicon-containing layer, have a sufficient curability to find commercial application as OPL, and be able to absorb NIR light used in optical auto-focusing. The present invention is predicated on this finding.

In one aspect, the invention provides a near-infrared absorptive layer-forming composition comprising

(A) at least one polymer comprising repeat units having the general formula (1):

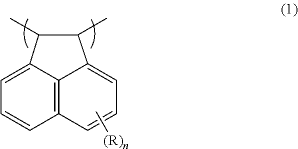

wherein R is hydrogen, a hydroxyl, carboxyl, hydroxymethyl, C₁-C₁₀ alkoxy, C₁-C₁₀ alkoxycarbonyl or C₁-C₁₀ acyloxy group, or a straight, branched or cyclic C₁-C₁₀ monovalent hydrocarbon group in which some hydrogen atoms may be substituted by halogen atoms and in which a —CH₂— moiety may be replaced by —O— or —C(═O)—, and n is an integer of 1 to 5,

(B) at least one near-infrared absorbing dye, and

(C) at least one solvent.

In a preferred embodiment, the polymer (A) comprises repeat units capable of undergoing crosslinking reaction in the presence of an acid. Typically, the repeat units capable of undergoing crosslinking reaction in the presence of an acid have an oxirane structure and/or oxetane structure.

In a preferred embodiment, the near-infrared absorbing dye (B) comprises at least one cyanine dye capable of absorbing radiation in a wavelength range of 500 to 1,200 nm.

The composition may further comprise at least one component selected from an acid generator, a crosslinker, and a surfactant.

In another aspect, the invention provides a multilayer stack film comprising a near-infrared absorptive layer which is formed by coating the near-infrared absorptive layer-forming composition defined above, and a photoresist layer which is formed on the near-infrared absorptive layer by coating a photoresist composition.

The multilayer film may further comprise a silicon-containing layer disposed beneath the photoresist layer, the near-infrared absorptive layer being disposed beneath the silicon-containing layer.

In a preferred embodiment, the near-infrared absorptive layer functions as a layer for absorbing near-infrared radiation used in optical auto-focusing. In another preferred embodiment, the near-infrared absorptive layer functions as an antireflective coating for preventing reflection of exposure radiation used in resist pattern formation.

### ADVANTAGEOUS EFFECTS OF INVENTION

By coating a near-infrared absorptive layer-forming composition according to the invention, a near-infrared absorptive layer can be formed. When a multilayer film comprising the near-infrared absorptive layer and a photoresist layer is used in optical lithography, the detection accuracy of the currently employed optical auto-focusing method is improved. This allows the optical lithography to produce a definite projection image with an improved contrast, succeeding in forming a better photoresist pattern.

### BRIEF DESCRIPTION OF DRAWINGS

FIG. 1 is a diagram showing reflectivity versus Si-containing layer thickness measured for a multilayer film of ArF photoresist layer/Si-containing layer/OPL on a silicon wafer wherein the OPL is based on Polymer 1 synthesized in Example.

FIG. 2 is a diagram showing reflectivity versus Si-containing layer thickness measured for a multilayer film of ArF photoresist layer/Si-containing layer/OPL on a silicon wafer wherein the OPL is based on Polymer 5 synthesized in Example.

FIG. 3 is a ¹H-NMR/DMSO-d₆ spectrum of NIR absorbing dye D2 synthesized in Example.

FIG. 4 is a ¹⁹F-NMR/DMSO-d₆ spectrum of NIR absorbing dye D2 synthesized in Example.

FIG. 5 is a ¹H-NMR/DMSO-d₆ spectrum of NIR absorbing dye D3 synthesized in Example.

FIG. 6 is a ¹⁹F-NMR/DMSO-d₆ spectrum of NIR absorbing dye D3 synthesized in Example.

FIG. 7 is a ¹H-NMR/DMSO-d₆ spectrum of NIR absorbing dye D4 synthesized in Example.

FIG. 8 is a ¹⁹F-NMR/DMSO-d₆ spectrum of NIR absorbing dye D4 synthesized in Example.

FIG. 9 is a ¹H-NMR/DMSO-d₆ spectrum of NIR absorbing dye D5 synthesized in Example.

FIG. 10 is a ¹⁹F-NMR/DMSO-d₆ spectrum of NIR absorbing dye D5 synthesized in Example.

FIG. 11 is a diagram showing the extinction coefficient over a wavelength range of 400 to 1,200 nm of a NIR absorptive layer formed from a NIR absorptive layer-forming composition of Example 2.

### DESCRIPTION OF EMBODIMENTS

The terms “a” and “an” herein do not denote a limitation of quantity, but rather denote the presence of at least one of the referenced item. As used herein, the notation (Cₙ—Cₘ) means a group containing from n to m carbon atoms per group. As used herein, the term “layer” is used interchangeably with “film” or “coating.”

The abbreviations and acronyms have the following meaning.

NIR: near infrared radiation

OPL: organic planarization layer

Mw: weight average molecular weight

Mn: number average molecular weight

Mw/Mn: molecular weight distribution or dispersity

GPC: gel permeation chromatography

PGMEA: propylene glycol monomethyl ether acetate

The NIR absorptive layer-forming composition is defined as comprising (A) at least one polymer comprising repeat units having the general formula (1), (B) at least one NIR absorbing dye, and (C) at least one solvent.

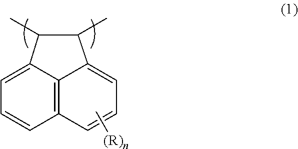

Herein R is hydrogen, a hydroxyl, carboxyl, hydroxymethyl, C₁-C₁₀ alkoxy, C₁-C₁₀ alkoxycarbonyl or C₁-C₁₀ acyloxy group, or a straight, branched or cyclic C₁-C₁₀ monovalent hydrocarbon group. In the hydrocarbon group, some hydrogen atoms may be substituted by halogen atoms and a —CH₂— moiety may be replaced by —O— or —C(═O)—. The subscript n is an integer of 1 to 5.

In formula (1), R is hydrogen, a hydroxyl group, carboxyl group, hydroxymethyl group, C₁-C₁₀ alkoxy group, C₁-C₁₀ alkoxycarbonyl group or C₁-C₁₀ acyloxy group, or a straight, branched or cyclic C₁-C₁₀ monovalent hydrocarbon group. Examples of straight, branched or cyclic monovalent hydrocarbon groups are hydrocarbons including methane, ethane, propane, n-butane, n-pentane, n-hexane, n-heptane, n-octane, n-nonane, n-decane, 2-methylpropane, 2-methylbutane, 2,2-dimethylpropane, 2-methylpentane, 2-methylhexane, 2-methylheptane, cyclopentane, cyclohexane, methylcyclopentane, methylcyclohexane, ethylcyclopentane, methylcycloheptane, ethylcyclohexane, norbornane, adamantane, benzene, toluene, ethylbenzene, n-propylbenzene, 2-propylbenzene, n-butylbenzene, t-butylbenzene, and naphthalene, with one hydrogen atom being eliminated. In these hydrocarbon groups, some hydrogen atoms may be substituted by halogen atoms and a —CH₂— moiety may be replaced by —O— or —C(═O)—.

Examples of the C₁-C₁₀ alkoxy group include groups R′O-wherein R′ stands for any of the above-illustrated monovalent hydrocarbon groups.

Examples of the C₁-C₁₀ alkoxycarbonyl group include methoxycarbonyl, ethoxycarbonyl, n-propyloxycarbonyl, 2-propyloxycarbonyl, butoxycarbonyl, tert-butoxycarbonyl, n-propyloxycarbonyl, tert-amyloxycarbonyl, cyclopropyloxycarbonyl, n-hexyloxycarbonyl, and cyclohexyloxycarbonyl.

Examples of the C₁-C₁₀ acyloxy group include formyloxy, acetyloxy, ethylcarbonyloxy, n-propylcarbonyloxy, 2-propylcarbonyloxy, n-butylcarbonyloxy, sec-butylcarbonyloxy, tert-butylcarbonyloxy, n-pentylcarbonyloxy, tert-amylcarbonyloxy, cyclopentylcarbonyloxy, and cyclohexylcarbonyloxy.

The polymer as component (A) should preferably comprise repeat units of at least one type which undergo crosslinking reaction in the presence of acid for forming a denser NIR-absorptive layer, for example, repeat units of at least one type containing a hydroxyl group, cyclic ether structure such as oxirane or oxetane, or carboxyl group. When the polymer (A) comprises repeat units capable of crosslinking reaction, a hard, dense NIR-absorptive layer can be formed, which is effective for preventing the NIR-absorptive layer from being thinned and the NIR-absorbing dye from being leached out of the layer when another layer such as a silicon-containing layer is deposited thereon. Among others, oxirane or oxetane structure-bearing repeat units which undergo crosslinking reaction in the presence of acid are most preferred because they have high acid reactivity and enable to form a dense layer.

Examples of suitable repeat units which undergo crosslinking reaction in the presence of acid are given below, but not limited thereto.

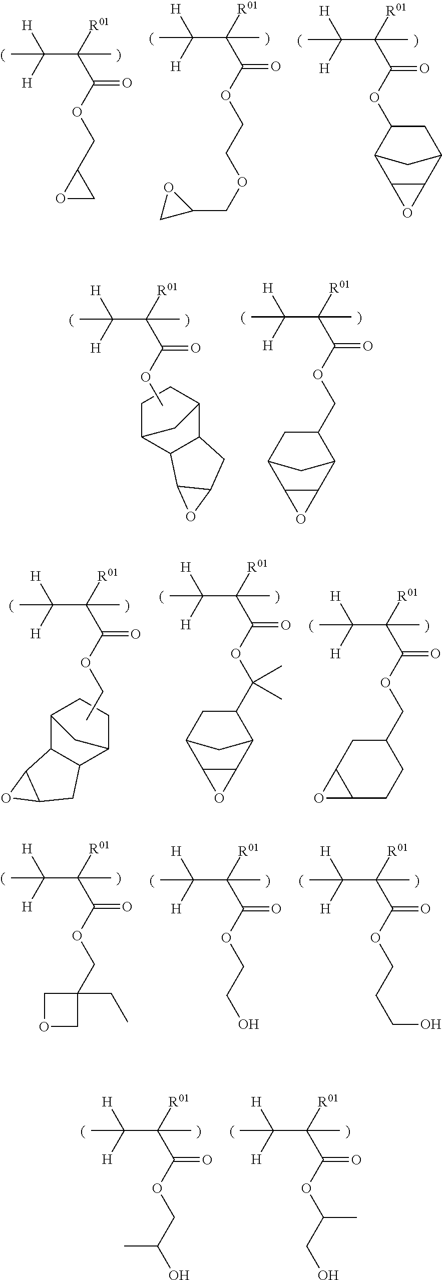

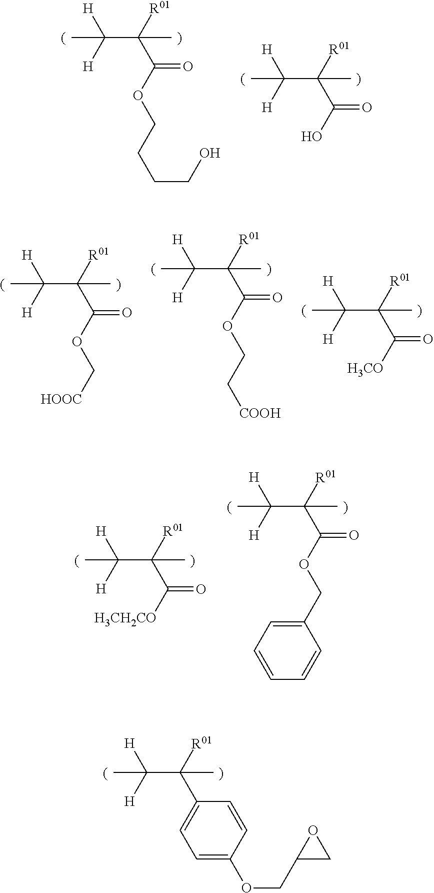

Herein R⁰¹ is hydrogen, methyl, fluorine, hydroxymethyl or trifluoromethyl.

In the polymer (A), aromatic ring-bearing repeat units other than the repeat units of formula (1) may be incorporated for tailoring optical properties. Examples of aromatic ring-bearing repeat units are given below, but not limited thereto.

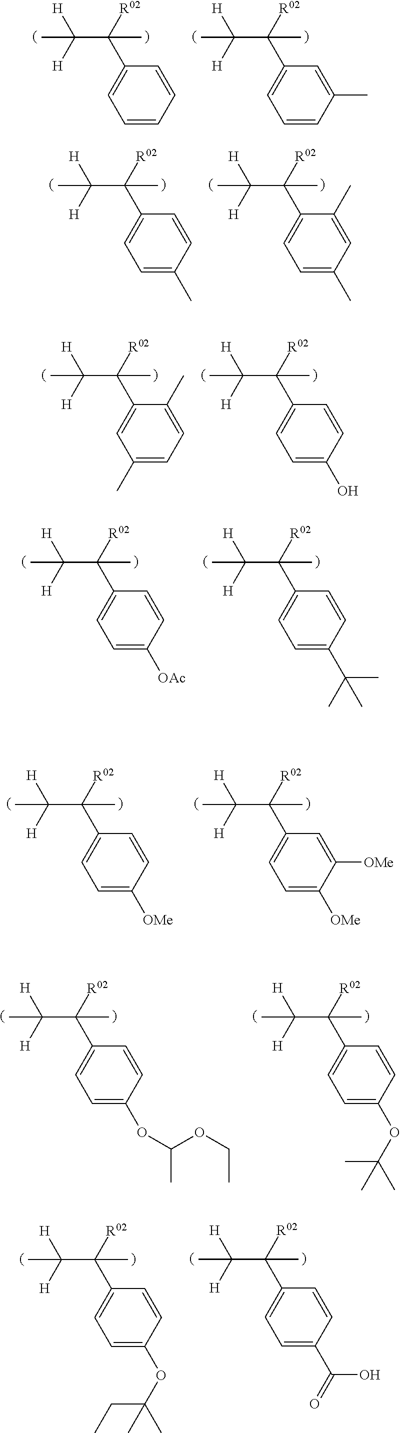

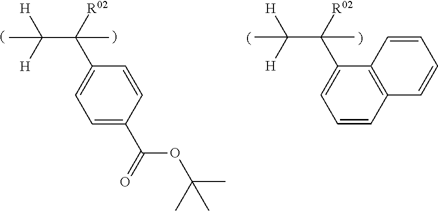

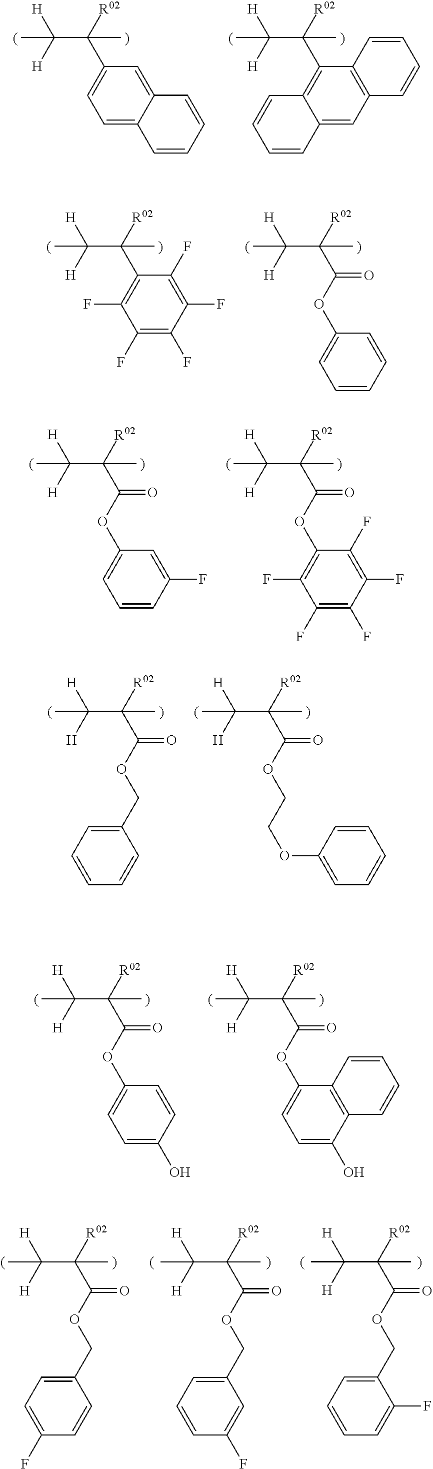

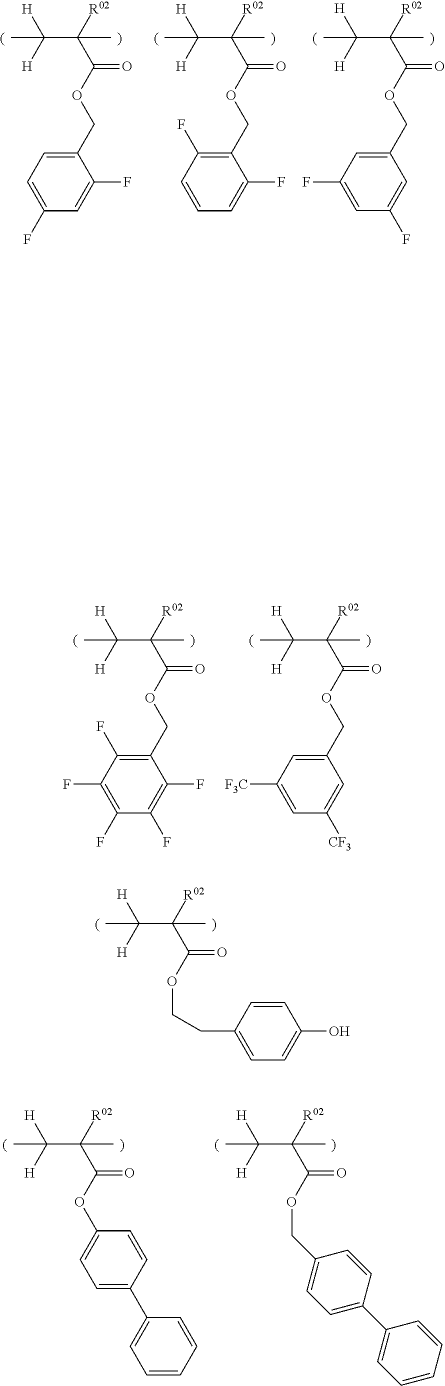

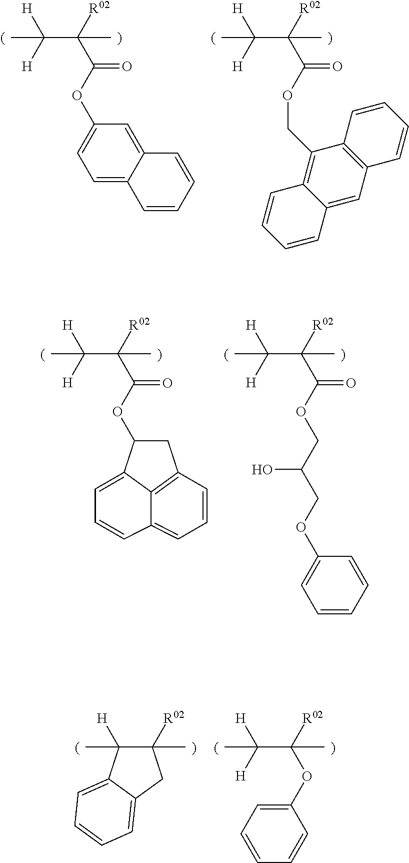

Herein R⁰² is hydrogen, methyl, fluorine or trifluoromethyl, Me stands for methyl, and Ac stands for acetyl.

When a NIR absorptive layer is formed using the NIR absorptive layer-forming composition, a certain combination of a polymer with a NIR absorbing dye may result in defective layer formation, failing in coverage of the entire wafer surface with a layer of a uniform thickness. To avoid such a phenomenon, repeat units of at least one type commonly used in the base resin of photoresist material, for example, repeat units having an acid labile group, lactone structure-bearing repeat units, hydroxyl-bearing repeat units, hydrocarbon-bearing repeat units, and halogen-bearing repeat units may be incorporated into the polymer. For the same purpose, repeat units of at least one type derived from such monomers as substituted (meth)acrylates, substituted norbornenes, and unsaturated acid anhydrides may also be incorporated. Examples of these repeat units are given below, but not limited thereto.

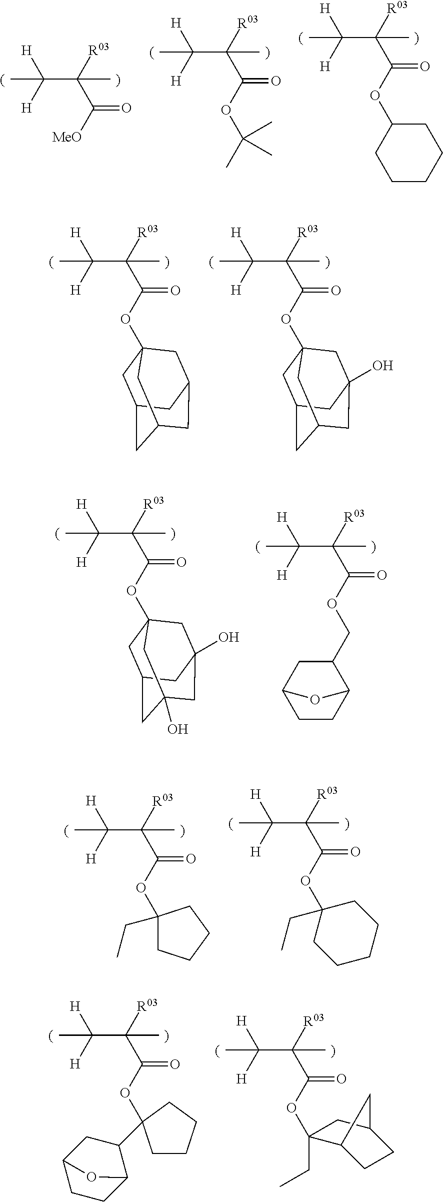

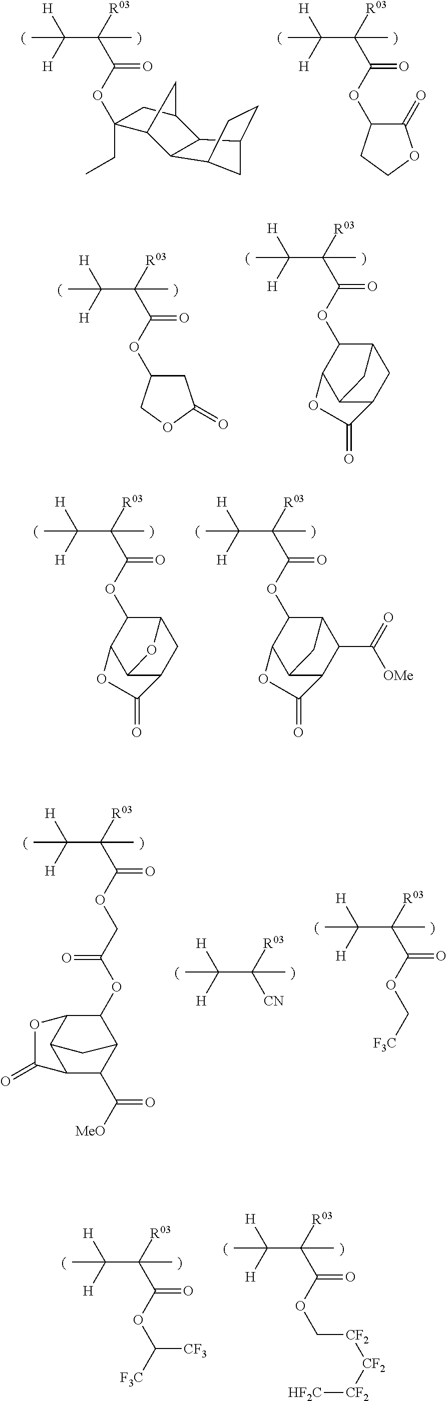

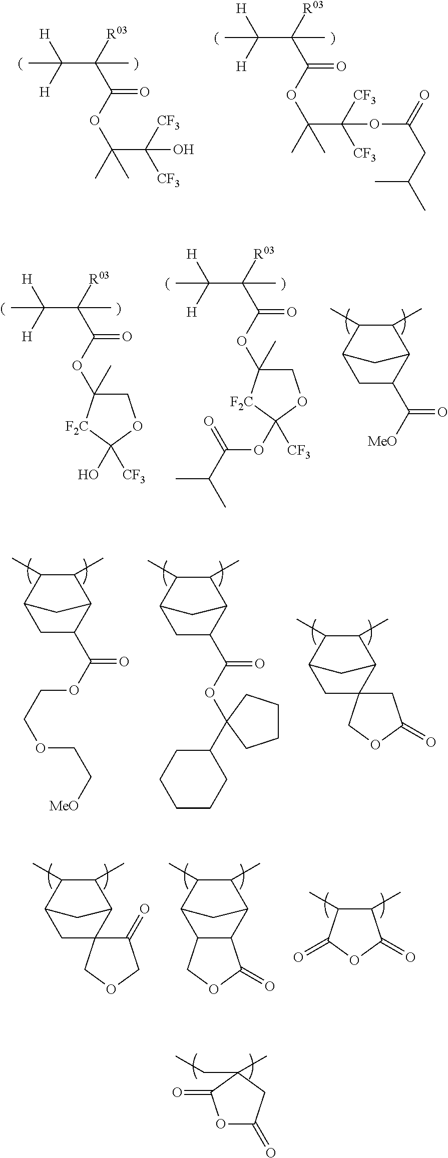

Herein R⁰³ is hydrogen, methyl, fluorine or trifluoromethyl, and Me stands for methyl.

The polymer (A) may comprise individual repeat units in a preferred compositional proportion range as shown below, but is not limited thereto. Specifically, the polymer may preferably comprise:

5 to 90 mol %, more preferably 8 to 80 mol %, and even more preferably 10 to 70 mol % of repeat units of formula (1),

5 to 90 mol %, more preferably 8 to 80 mol %, and even more preferably 10 to 70 mol %, in total, of repeat units which undergo acid-assisted crosslinking reaction,

0 to 50 mol %, more preferably 1 to 45 mol %, and even more preferably 3 to 40 mol %, in total, of aromatic ring-bearing repeat units other than the repeat units of formula (1), and

0 to 40 mol %, more preferably 1 to 30 mol %, and even more preferably 3 to 20 mol %, in total, of other repeat units, provided that these units total to 100 mol %.

Monomers from which repeat units of formula (1) are derived are commercially available. They may also be prepared using any well-known organic chemistry formulation.

Likewise, monomers from which repeat units capable of acid-assisted crosslinking reaction, aromatic ring-bearing repeat units other than the repeat units of formula (1), and other repeat units are derived are commercially available. They may also be prepared using any well-known organic chemistry formulation.

The polymerization reaction to produce the polymer (A) may be any of well-known polymerization reactions, but preferably radical polymerization.

For radical polymerization, preferred reaction conditions include (1) a solvent selected from hydrocarbon solvents such as benzene, toluene and xylene, glycol solvents such as propylene glycol monomethyl ether and propylene glycol monomethyl ether acetate, ether solvents such as diethyl ether, diisopropyl ether, dibutyl ether, tetrahydrofuran, and 1,4-dioxane, ketone solvents such as acetone, methyl ethyl ketone, methyl isobutyl ketone and methyl amyl ketone, ester solvents such as ethyl acetate, propyl acetate, butyl acetate and ethyl lactate, lactone solvents such as γ-butyrolactone, and alcohol solvents such as ethanol and isopropyl alcohol; (2) a polymerization initiator selected from well-known radical polymerization initiators including azo compounds such as
2,2′-azobisisobutyronitrile,
2,2′-azobis-2-methylisobutyronitrile,
dimethyl 2,2′-azobisisobutyrate.
2,2′-azobis-2,4-dimethylvaleronitrile,
1,1′-azobis(cyclohexane-1-carbonitrile), and
4,4′-azobis(4-cyanovaleric acid), and peroxides such as lauroyl peroxide and benzoyl peroxide; (3) a radical chain transfer agent, if necessary for molecular weight control, selected from thiol compounds including 1-butanethiol,
2-butanethiol, 2-methyl-1-propanethiol, 1-octanethiol,
1-decanethiol, 1-tetradecanethiol, cyclohexanethiol,
2-mercaptoethanol, 1-mercapto-2-propanol,
3-mercapto-1-propanol, 4-mercapto-1-butanol,
6-mercapto-1-hexanol, 1-thioglycerol, thioglycolic acid,
3-mercaptopropionic acid, and thiolactic acid; (4) a reaction temperature in the range of about 0° C. to about 140° C.; and (5) a reaction time in the range of about 0.5 to about 48 hours. Reaction parameters outside these ranges need not be excluded.

The polymer (A) preferably has a weight average molecular weight (Mw) of 1,000 to 200,000, and more preferably 2,000 to 180,000, as measured by GPC versus polystyrene standards. A polymer having too high a Mw may not dissolve in a solvent or may dissolve in a solvent to form a solution, which may be less effective to coat, failing to form a layer of uniform thickness over the entire wafer surface. Also, when a polymer layer is formed on a patterned substrate, the layer may fail to cover the pattern without leaving voids. On the other hand, a polymer having too low a Mw may have a problem that when a polymer layer is overlaid with another layer, the polymer layer is in part washed away and thinned.

Component (B) is a near-infrared absorbing dye. It may be any dye capable of absorbing radiation in a wavelength range of 500 to 1,200 nm. Suitable NIR-absorbing dyes include the structures of the general formulae (2) to (6), but are not limited thereto.

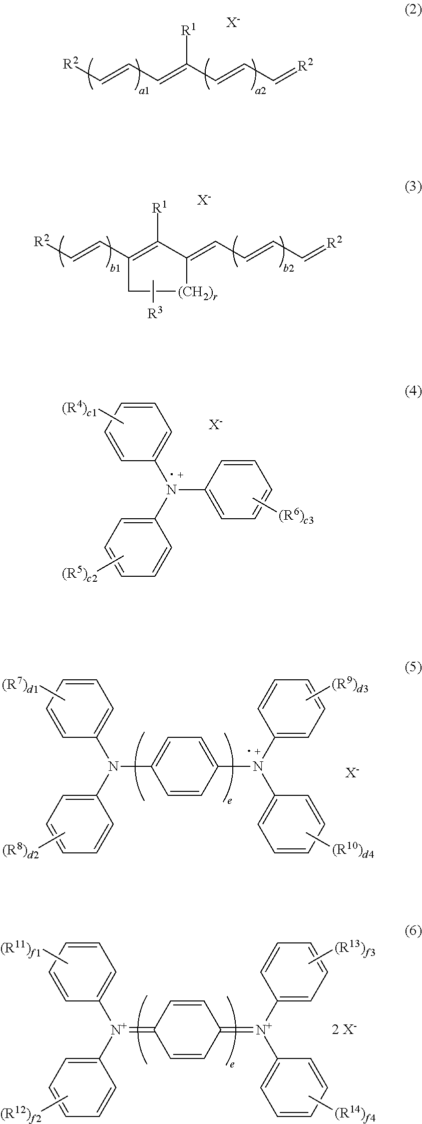

Herein, R¹ is hydrogen, halogen, cyano group, —R^{1a}, —OR^{1a}, —SR^{1a}, —SO₂R^{1a}, —O₂CR^{1a}, —CO₂R^{1a}, or —N(R^{1a})₂. R^{1a} is a straight, branched or cyclic C₁-C₂₀ monovalent hydrocarbon group, in which some hydrogen may be substituted by halogen or cyano group, or in which a —CH₂— moiety may be replaced by an oxygen atom, sulfur atom or —C(═O)O—. R² is an organic group containing nitrogen and a cyclic structure. R³ is a straight, branched or cyclic C₁-C₅ monovalent hydrocarbon group. R⁴, R⁵, and R⁶ are each independently hydrogen, halogen, cyano, amino, —R^{1a}, —OR^{1a}, —SR^{1a}, —SO₂R^{1a}, —O₂CR^{1a}, —CO₂R^{1a}, or —N(R^{1a})₂. R⁷, R⁸, R⁹, and R¹⁰ are each independently hydrogen, halogen, cyano, amino, —R^{1a}, —OR^{1a}, —SR^{1a}, —SO₂R^{1a}, —O₂CR^{1a}, —CO₂R^{1a}, or —N(R^{1a})₂. R¹¹, R¹², R¹³, and R¹⁴ are each independently hydrogen, halogen, cyano, amino, —R^{1a}, —OR^{1a}, —SR^{1a}, —SO₂R^{1a}, —O₂CR^{1a}, —CO₂R^{1a}, or —N(R^{1a})₂. Notably R^{1a} is as defined above. X⁻ is an anion. The subscripts a1 and a2 are each independently an integer of 0 to 5; b1 and b2 are each independently an integer of 0 to 5; r is 1 or 2; c1, c2 and c3 are each independently an integer of 0 to 5; d1, d2, d3, and d4 are each independently an integer of 0 to 5; e is 1 or 2; f1, f2, f3, and f4 are each independently an integer of 0 to 5.

In formulae (2) and (3), R¹ is hydrogen, halogen, cyano group, —R^{1a}, —OR^{1a}, —SR^{1a}, —SO₂R^{1a}, —O₂CR^{1a}, —CO₂R^{1a}, or —N(R^{1a})₂, wherein R^{1a} is a straight, branched or cyclic C₁-C₂₀ monovalent hydrocarbon group, in which some hydrogen may be substituted by halogen or cyano group, or in which a —CH₂— moiety may be replaced by an oxygen atom, sulfur atom or —C(═O)O—. Examples of the monovalent hydrocarbon group are hydrocarbons including methane, ethane, propane, n-butane, n-pentane, n-hexane, n-heptane, n-octane, n-nonane, n-decane, 2-methylpropane, 2-methylbutane, 2,2-dimethylpropane, 2-methylpentane, 2-methylhexane, 2-methylheptane, cyclopentane, cyclohexane, methylcyclopentane, methylcyclohexane, ethylcyclopentane, methylcycloheptane, ethylcyclohexane, norbornane, adamantane, benzene, toluene, ethylbenzene, n-propylbenzene, 2-propylbenzene, n-butylbenzene, t-butylbenzene, n-pentylbenzene, and naphthalene, with one hydrogen atom being eliminated.

In formulae (2) and (3), R² is an organic group containing nitrogen and a cyclic structure, examples of which include structures of the general formulae (7) and (8).

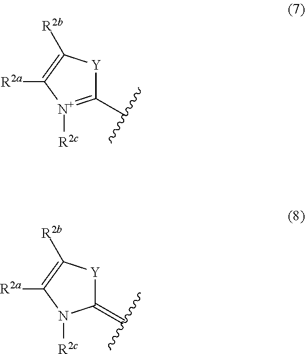

In formulae (7) and (8), R^{2a} and R^{2b} are each independently a straight, branched or cyclic C₁-C₂₀ monovalent hydrocarbon group in which some hydrogen may be substituted by halogen or cyano group, or in which a —CH₂— moiety may be replaced by an oxygen atom, sulfur atom or —C(═O)O—. R^{2a} and R^{2b} may bond together to form a ring, specifically a C₅-C₁₅, alicyclic or aromatic ring, with the carbon atoms to which they are attached. Y is an oxygen atom, sulfur atom or —C(R^{Y})₂— wherein R^{Y} is hydrogen or a C₁-C₁₀ monovalent hydrocarbon group. R^{Y} and R^{2b} may bond together to form a ring, specifically a C₅-C₁₅ alicyclic or aromatic ring, with the carbon atoms to which they are attached. R^{2c} is a straight, branched or cyclic C₁-C₂₀ monovalent hydrocarbon group in which some hydrogen may be substituted by halogen or cyano group, or in which a —CH₂— moiety may be replaced by an oxygen atom, sulfur atom or —C(═O)O—.

In formulae (2) and (3), either one of R² must be a cationic group like formula (7). It is excluded that both R² are cationic groups like formula (7).

In formula (3), R³ is a straight, branched or cyclic C₁-C₅ monovalent hydrocarbon group. Suitable monovalent hydrocarbon groups include methyl, ethyl, n-propyl, 2-propyl, n-butyl, 2-butyl, isobutyl, tert-butyl, n-pentyl, tert-amyl, and cyclopentyl.

In formula (4), R⁴, R⁵, and R⁶ are each independently hydrogen, halogen, cyano, amino, —R^{a}, —OR^{1a}, —SO₂R^{1a}, —O₂CR^{1a}, —CO₂R^{1a}, or —N(R^{1a})₂. Inter alia, preference is given to amino, dimethylamino, diethylamino, dipropylamino, dibutylamino, diisobutylamino, di-sec-butylamino, bis(2,2,2-trifluoroethyl)amino, bis(4,4,4-trifluorobutyl)amino, and bis(4-hydroxybutyl)amino.

In formula (5), R⁷, R⁸, R⁹, and R¹⁰ are each independently hydrogen, halogen, cyano, amino, —R^{1a}, —OR^{1a}, —SR^{1a}, —SO₂R^{1a}, —O₂CR^{1a}, —CO₂R^{1a}, or —N(R^{1a})₂. Inter alia, preference is given to amino, dimethylamino, diethylamino, dipropylamino, dibutylamino, diisobutylamino, di-sec-butylamino, bis(2,2,2-trifluoroethyl)amino, bis(4,4,4-trifluorobutyl)amino, and bis(4-hydroxybutyl)amino.

In formula (6), R¹¹, R¹², R¹³, and R¹⁴ are each independently hydrogen, halogen, cyano, amino, —R^{1a}, —OR^{1a}, —SR^{1a}, —SO₂R^{1a}, —O₂CR^{1a}, —CO₂R^{1a}, or —N(R^{1a})₂. Inter alia, preference is given to amino, dimethylamino, diethylamino, dipropylamino, dibutylamino, diisobutylamino, di-sec-butylamino, bis(2,2,2-trifluoroethyl)amino, bis(4,4,4-trifluorobutyl)amino, and bis(4-hydroxybutyl)amino.

Notably R^{1a} is as defined above in conjunction with R^{1a}.

In formulae (2) to (6), X⁻ is an anion. Exemplary anions include halide ions such as chloride, bromide and iodide ions, fluoroalkylsulfonates such as triflate, 1,1,1-trifluoroethanesulfonate, pentafluoroethanesulfonate, and nonafluorobutanesulfonate, arylsulfonates such as tosylate, benzenesulfonate, 4-fluorobenzenesulfonate, and 1,2,3,4,5-pentafluorobenzenesulfonate, alkylsulfonates such as mesylate and butanesulfonate, conjugate bases of imide acids such as bis(trifluoromethylsulfonyl)imide,
bis(perfluoroethylsulfonyl)imide,
bis(perfluoropropylsulfonyl)imide, and
bis(perfluorobutylsulfonyl)imide, methide acids such as
tris(trifluoromethylsulfonyl)methide and
tris(perfluoroethylsulfonyl)methide, and mineral acids such as BF₄⁻, PF₆⁻, ClO₄⁻, NO₃⁻, and SbF₆⁻.

In formula (2), a1 and a2 are each independently an integer of 0 to 5, preferably 0 to 2. In formula (3), b1 and b2 are each independently an integer of 0 to 5, preferably 0 to 2, and r is 1 or 2. In formula (4), c1, c2 and c3 are each independently an integer of 0 to 5, preferably 0 to 2. In formula (5), d1, d2, d3, and d4 are each independently an integer of 0 to 5, preferably 0 to 2. In formula (6), f1, f2, f3, and f4 are each independently an integer of 0 to 5, preferably 0 to 2. In formulae (5) and (6), e is 1 or 2.

Since the NIR-absorptive layer according to the invention is formed through acid-assisted crosslinking reaction, X⁻ is preferably a conjugate base of strong acid so that the layer may be more curable and dense. If a conjugate base of weak acid is used, an anion exchange with the acid generator may occur whereby the crosslinking reaction is retarded. Specifically, fluoroalkylsulfonates, imidates, and methidates are preferably used.

It is noted that the NIR-absorbing dye (B) may be amphoteric and in this case, X⁻ is unnecessary.

Of the foregoing NIR-absorbing dyes, those cyanine dyes of formulae (2) and (3) capable of absorbing radiation in a wavelength range of 500 to 1,200 nm are preferred because of heat resistance and solvent solubility.

Also these NIR-absorbing dyes may be used alone or in admixture of two or more. When a combination of two or more dyes is used, a plurality of cations of the structures having formulae (2) to (6) may be used. When two or more dyes having different wavelength bands of NIR absorption are used in combination, an absorption wavelength band which is not available with a single dye is achievable. This provides for effective absorption of NIR light used in optical auto-focusing, sometimes leading to an improvement in the accuracy of focusing.

The cations of the NIR-absorbing dyes of formulae (2) to (6) are illustrated by the following exemplary structures, but not limited thereto.

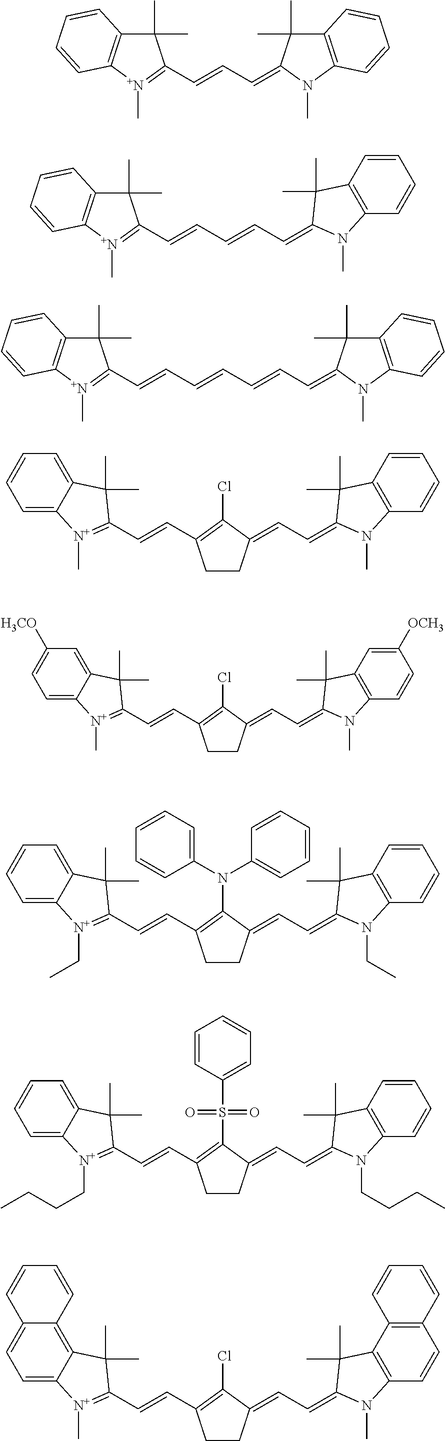

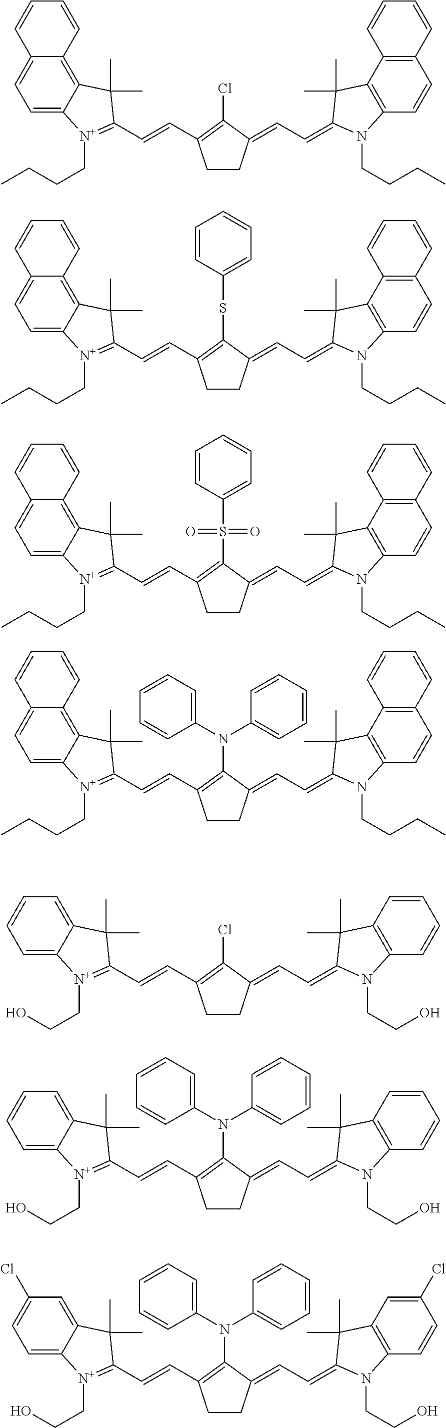

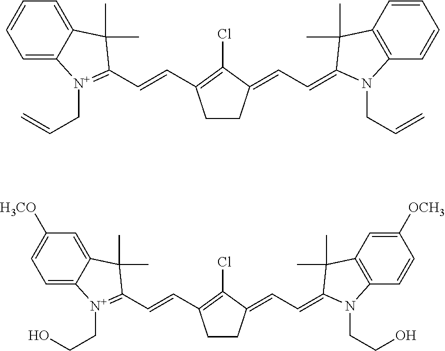

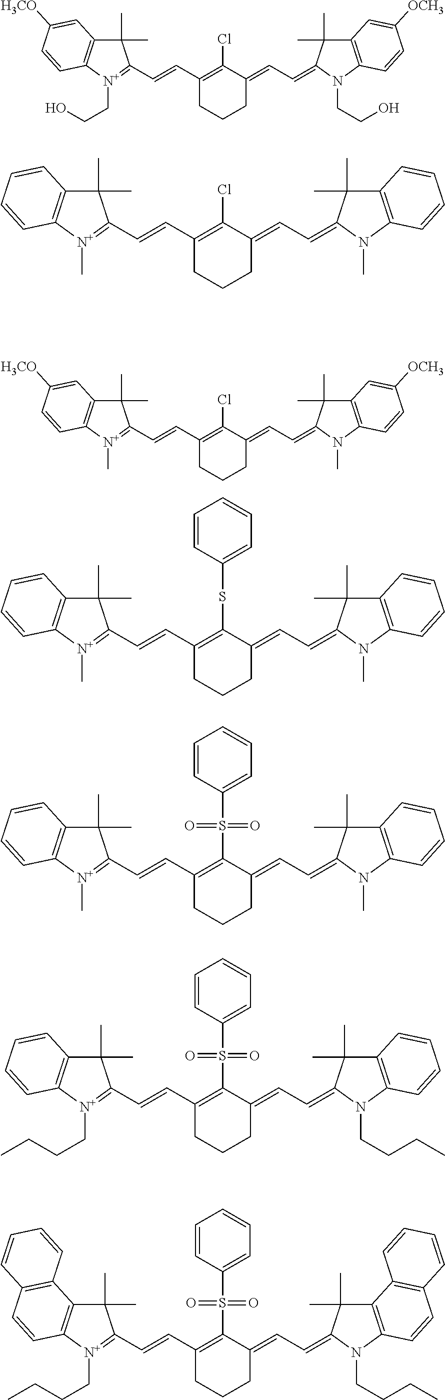

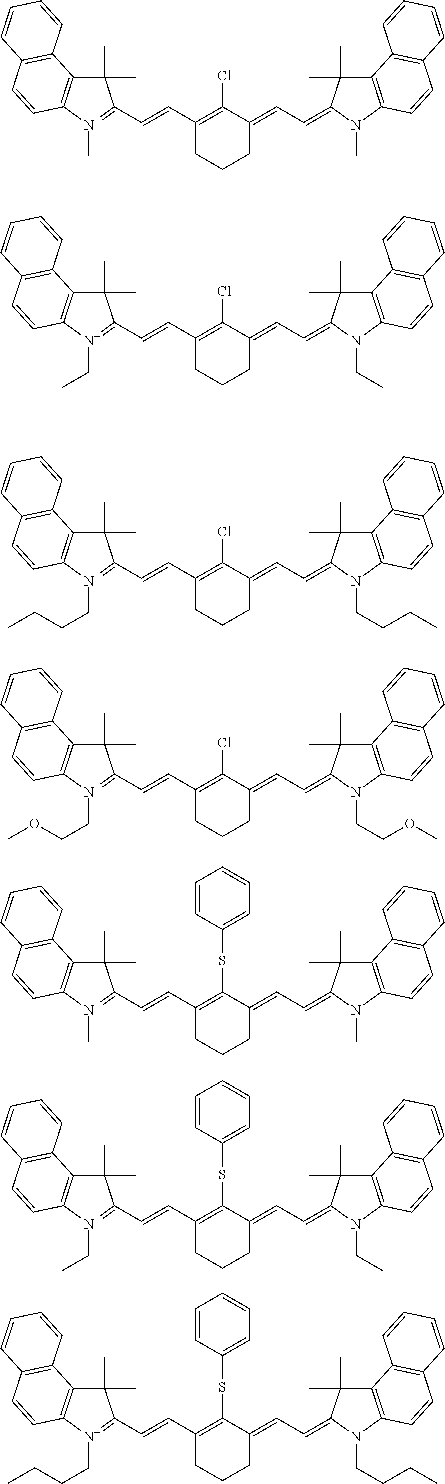

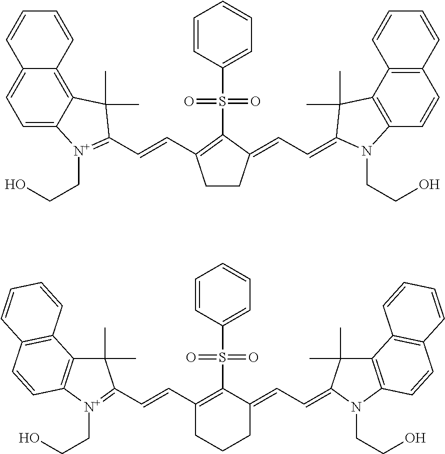

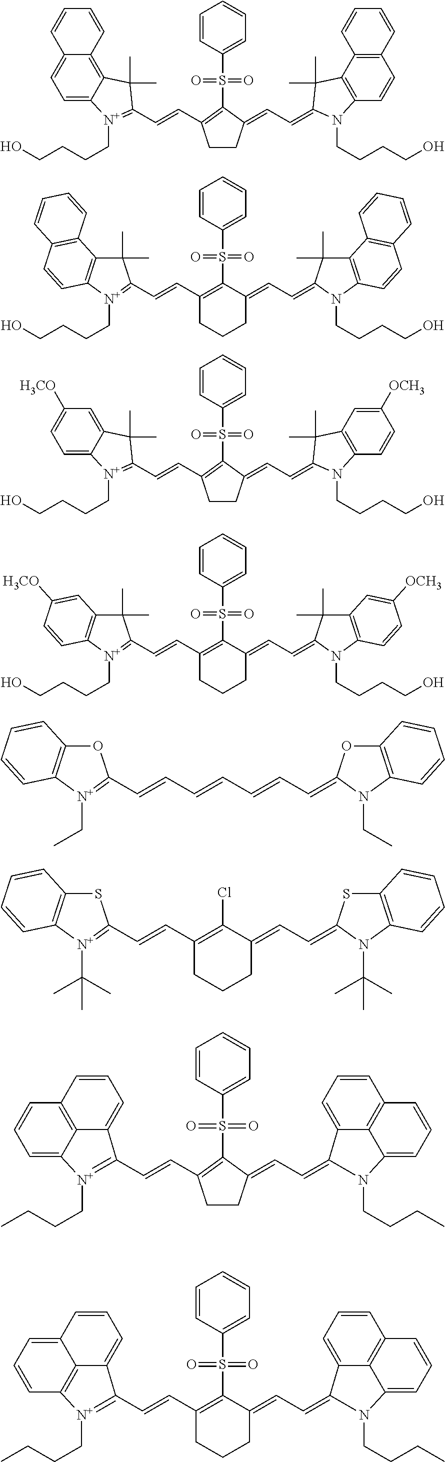

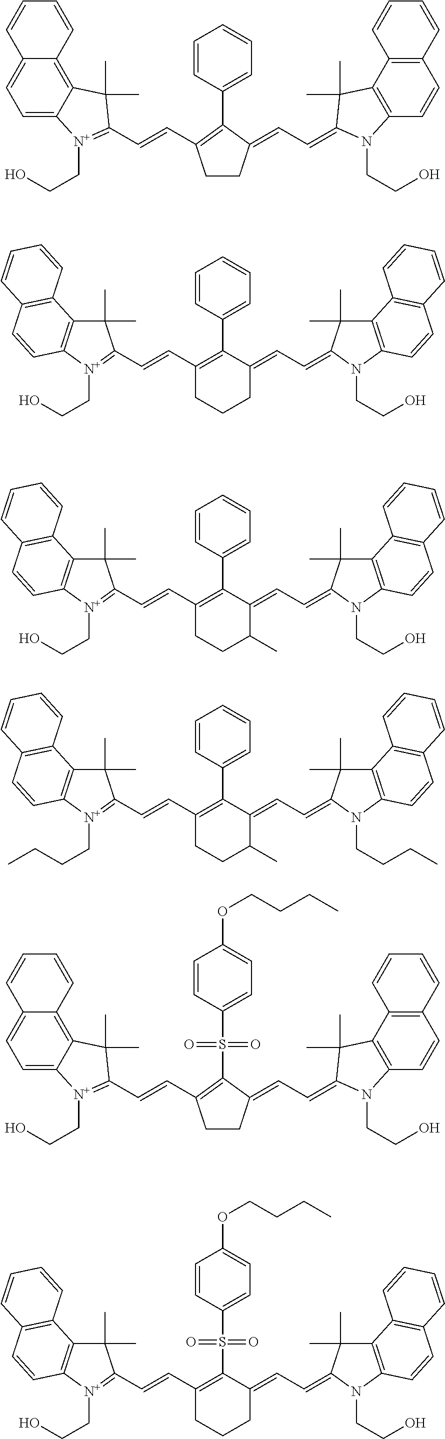

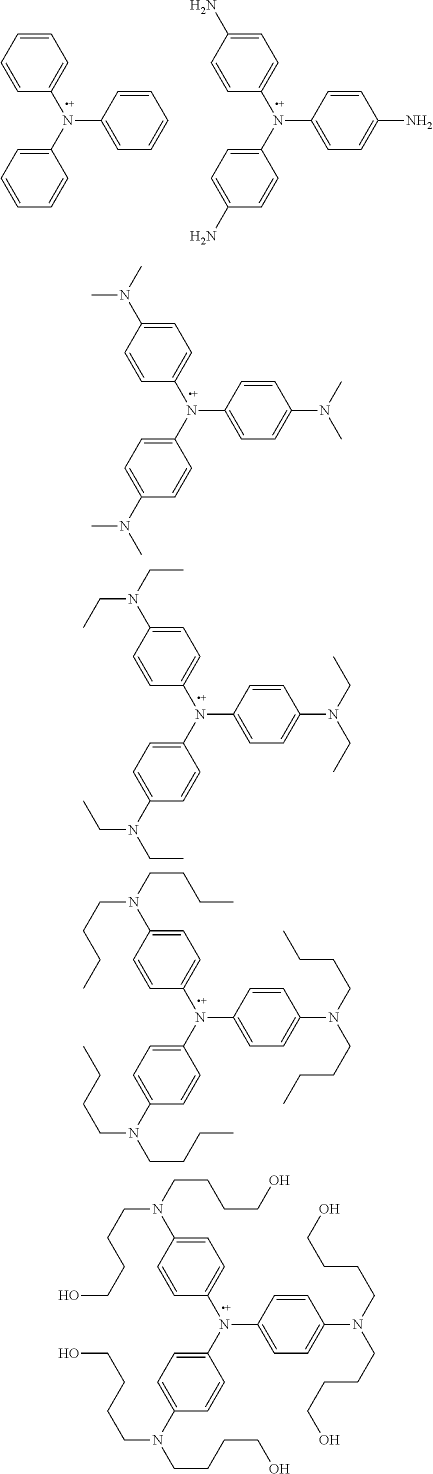

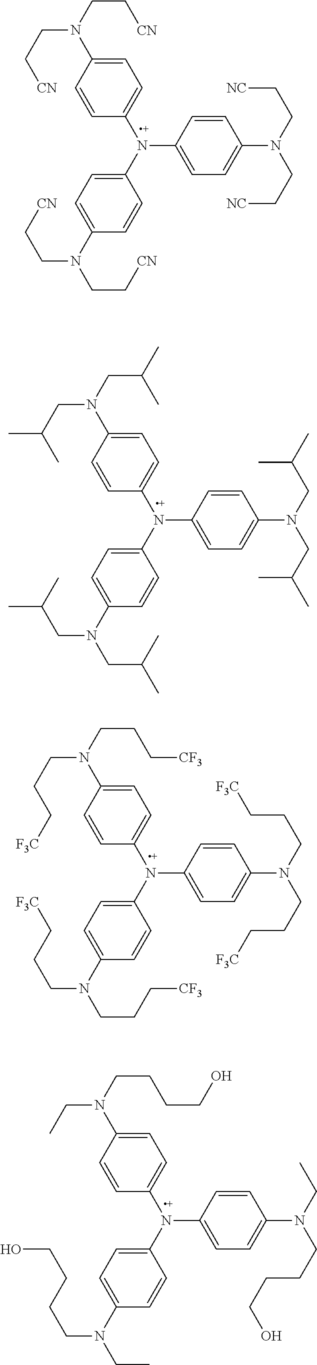

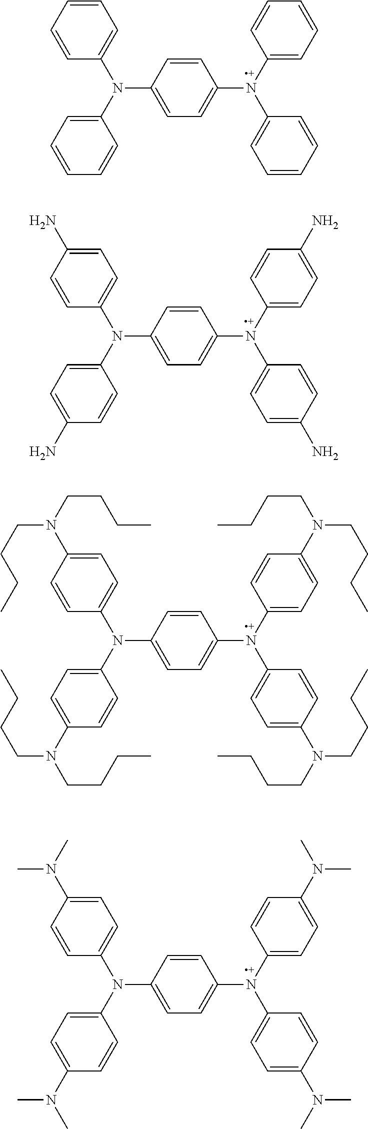

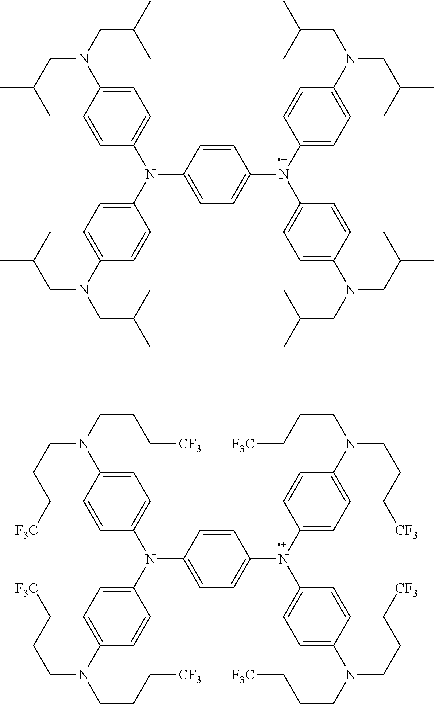

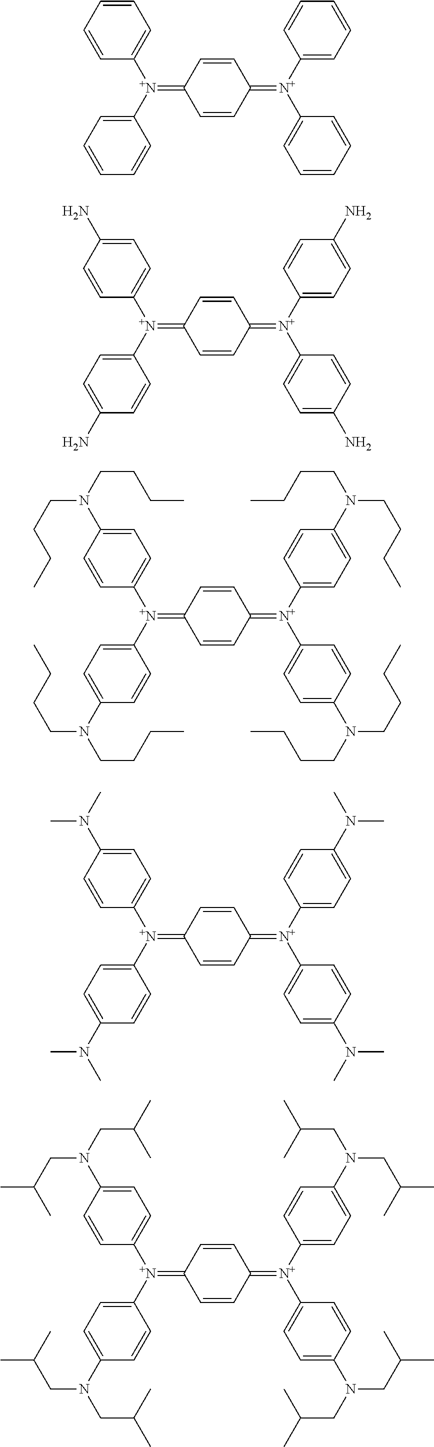

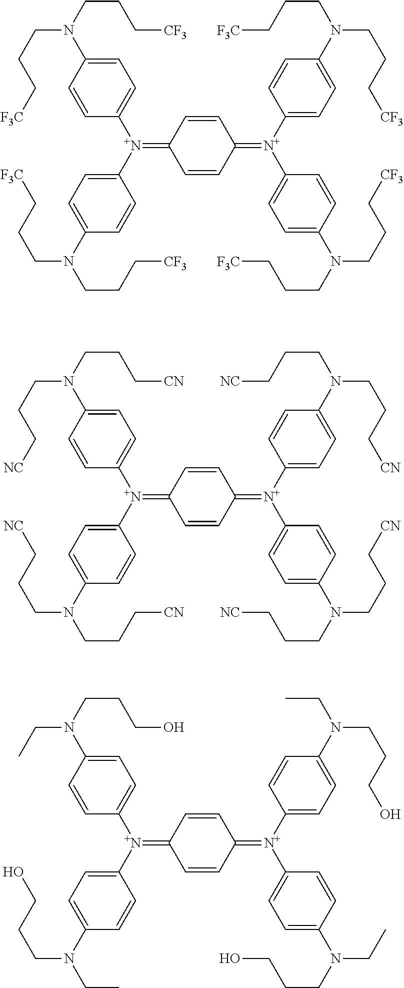

Examples of the ampho-ion structure are illustrated below, but not limited thereto.

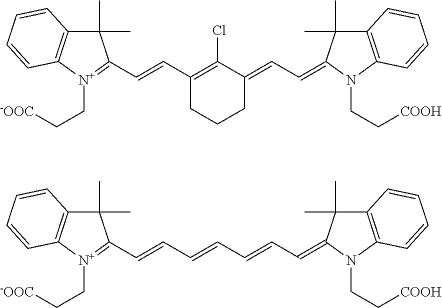

As the NIR-absorbing dye, commercially available dyes may be used as purchased, or derivatives using them as the precursor may be used. They may also be prepared by any well-known organic chemical formulation.

The NIR-absorbing dye is preferably used in an amount of 20 to 300 parts, more preferably 49 to 100 parts by weight per 100 parts by weight of the overall polymer.

Component (C) is a solvent. The solvent used herein may be any organic solvent in which the polymer, acid generator, crosslinker and other components are soluble. Illustrative, non-limiting, examples of the organic solvent include ketones such as cyclohexanone and methyl-2-amylketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone. These solvents may be used alone or in combinations of two or more thereof. Of the above organic solvents, preferred are diethylene glycol dimethyl ether, 1-ethoxy-2-propanol, ethyl lactate, PGMEA, cyclohexanone, γ-butyrolactone, and mixtures thereof.

The organic solvent is preferably added in an amount of 900 to 20,000 parts by weight, more preferably 1,000 to 15,000 parts by weight per 100 parts by weight of the overall polymer.

In addition to the foregoing components (A) to (C), the NIR absorptive layer-forming composition preferably comprises an acid generator and a crosslinker, each at least one type. In the embodiment of the NIR absorptive layer-forming composition containing an acid generator and a crosslinker, crosslink formation of the polymer (A) can be promoted by bake following spin coating, leading to formation of a harder, denser layer. This prevents the NIR absorptive layer from being thinned or the NIR absorbing dye from being leached out of the layer when another layer such as a silicon-containing layer is coated immediately on the NIR absorptive layer.

The acid generator has a function of promoting crosslinking reaction during layer formation. While the acid generators include those capable of generating acid through thermal decomposition and those capable of generating acid upon light exposure, either one may be used.

While a variety of acid generators may be used in the NIR absorptive layer-forming composition, typical acid generators are illustrated in JP-A 2008-083668. The preferred acid generators are onium salts having α-fluoro-substituted sulfonate as an anion including
triethylammonium nonafluorobutanesulfonate,
(p-methoxyphenylmethyl)dimethylphenylammonium trifluoro-methanesulfonate,
bis(p-tert-butylphenyl)iodonium nonafluorobutanesulfonate,
triphenylsulfonium trifluoromethanesulfonate,
(p-tert-butoxyphenyl)diphenylsulfonium trifluoromethanesulfonate,
tris(p-tert-butoxyphenyl)sulfonium trifluoromethanesulfonate,
trinaphthylsulfonium trifluoromethanesulfonate,
cyclohexylmethyl(2-oxocyclohexyl)sulfonium trifluoromethanesulfonate,
(2-norbornyl)methyl(2-oxocyclohexyl)sulfonium trifluoro-methanesulfonate, and
1,2′-naphthylcarbonylmethyltetrahydrothiophenium triflate. The acid generators may be used alone or in admixture of two or more.

The acid generator is preferably added in an amount of 0.1 to 50 parts by weight, more preferably 0.5 to 40 parts by weight per 100 parts by weight of the overall polymer. Less than 0.1 pbw of the acid generator may generate an acid in an amount insufficient to promote crosslinking reaction whereas more than 50 pbw may give rise to a mixing phenomenon that the acid will migrate to the overlying layer.

The crosslinker has a function of promoting crosslinking reaction during layer formation. Suitable crosslinkers which can be added herein include melamine compounds, guanamine compounds, glycoluril compounds and urea compounds having substituted thereon at least one group selected from among methylol, alkoxymethyl and acyloxymethyl groups, epoxy compounds, isocyanate compounds, azide compounds, and compounds having a double bond such as an alkenyl ether group. Acid anhydrides, oxazoline compounds, and compounds having a plurality of hydroxyl groups are also useful as the crosslinker. Typical crosslinkers are illustrated in JP-A 2009-098639.

Preferred examples of the crosslinker include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof.

The crosslinker is preferably added in an amount of 0 to 50 parts by weight, more preferably 1 to 40 parts by weight per 100 parts by weight of the overall polymer. An appropriate amount of the crosslinker is effective for curing a layer. However, if the amount is more than 50 pbw, part of the crosslinker may be released as outgas upon layer formation, causing contamination to the exposure apparatus. The crosslinkers may be used alone or in admixture of two or more.

In a preferred embodiment, the NIR absorptive layer-forming composition further comprises at least one surfactant. When a NIR absorptive layer is formed by spin coating of the NIR absorptive layer-forming composition, a certain combination of a polymer with a NIR absorbing dye may result in defective layer formation, failing in coverage of the entire wafer surface with a layer of a uniform thickness. The addition of a surfactant to the NIR absorptive layer-forming composition can improve its coating characteristics, obviating defective layer formation.

Illustrative, non-limiting, examples of the surfactant include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene polyoxypropylene block copolymers, sorbitan fatty acid esters such as sorbitan monolaurate, sorbitan monopalmitate, and sorbitan monostearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants such as EFTOP EF301, EF303 and EF352 (Jemco Co., Ltd.), Megaface F171, F172, F173, R08, R30, R90 and R94 (DIC Corp.), Fluorad FC-430, FC-431, FC-4430 and FC-4432 (3M Sumitomo Co., Ltd.), Asahiguard AG710, Surflon S-381, S-382, S-386, SC101, SC102, SC103, SC104, SC105, SC106, KH-10, KH-20, KH-30 and KH-40 (Asahi Glass Co., Ltd.), and Surfynol E1004 (Nissin Chemical Industry Co., Ltd.); organosiloxane polymers KP341, X-70-092 and X-70-093 (Shin-Etsu Chemical Co., Ltd.), acrylic acid or methacrylic acid Polyflow No. 75 and No. 95 (Kyoeisha Kagaku Kogyo Co., Ltd.). Additional useful surfactants include partially fluorinated oxetane ring-opened polymers having the structural formula (surf-1).

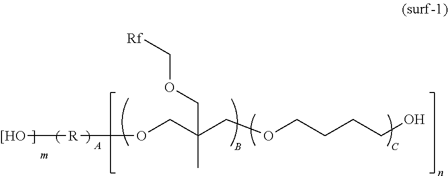

It is provided herein that R, Rf, A, B, C, m, and n are applied to only formula (surf-1), independent of their descriptions other than for the surfactant. R is a di- to tetra-valent C₂-C₅ aliphatic group. Exemplary divalent groups include ethylene, 1,4-butylene, 1,2-propylene, 2,2-dimethyl-1,3-propylene and 1,5-pentylene. Exemplary tri- and tetra-valent groups are shown below.

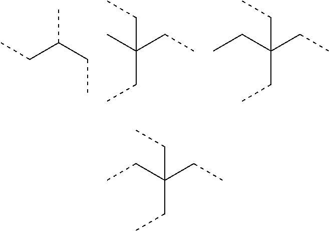

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. A is equal to 1, B is an integer of 2 to 25, and C is an integer of 0 to 10. Preferably, B is an integer of 4 to 20, and C is 0 or 1. Note that the above structural formula does not prescribe the arrangement of respective constituent units while they may be arranged either in blocks or randomly. For the preparation of surfactants in the form of partially fluorinated oxetane ring-opened polymers, reference should be made to U.S. Pat. No. 5,650,483, for example.

Of the foregoing surfactants, FC-4430, Surflon S-381, Surfynol E1004, KH-20, KH-30, and oxetane ring-opened polymers of formula (surf-1) are preferred. These surfactants may be used alone or in admixture.

To the NIR absorptive layer-forming composition, the surfactant is preferably added in an amount of up to 2 parts, more preferably up to 1 part by weight, and at least 0.0001 part, more preferably at least 0.001 part by weight, relative to 100 parts by weight of the overall polymer.

When the NIR absorptive layer-forming composition is coated, the resulting layer contains the dye capable of absorbing radiation in a wavelength range of 500 to 1,200 nm so that it may function as a layer for absorbing NIR radiation used in optical autofocus method.

Another embodiment of the invention is a multilayer film comprising a NIR absorptive layer which is formed on a substrate by coating the NIR absorptive layer-forming composition, and a photoresist layer which is formed on the NIR absorptive layer by coating a photoresist composition. In the practice of optical auto-focusing, the multilayer film prevents the NIR light transmitted by the resist layer from being reflected from the substrate and entering the focus detection system. This improves the accuracy of optical auto-focusing. Since the optical autofocus method used in the existing semiconductor fabrication site is applicable without substantial changes, the time taken for the method falls within a practically acceptable range.

The NIR absorptive layer is preferably used as an antireflective coating for exposure radiation used in optical lithography. Then the wafer layer stacking process currently used in the industry can be used without substantial modifications.

Due to thinning of resist layer and an etching selective ratio between resist layer and processable substrate, processing becomes more difficult. One current approach for obviating such difficulty is a trilayer process that uses a trilayer structure including a resist layer, a silicon-containing layer underneath the resist layer, and an underlayer (OPL) having a high carbon density and high etch resistance underneath the silicon-containing layer. On etching with oxygen gas, hydrogen gas or ammonia gas, a high etching selective ratio is established between the Si-containing layer and the underlayer, allowing the Si-containing layer to be thinned. Also the etching selective ratio between the single-layer resist layer and the Si-containing layer is relatively high, allowing the single-layer resist layer to be thinned. The reflection of exposure light may be effectively prevented by adjusting optical properties of these three layers.

When the NIR absorptive layer serves as the antireflective coating layer, it is most preferably used as the underlayer. This is because a polymer comprising repeat units of formula (1), when used as a base resin for the underlayer, displays optical properties enough to exert a high antireflective effect and has high etch resistance.

The method of forming a NIR absorptive layer according to the invention is described. Like conventional photoresist layers, the NIR absorptive layer can be formed on a substrate by any suitable coating techniques including spin coating, roll coating, flow coating, dip coating, spray coating, and doctor coating. Once the NIR absorptive layer-forming composition is coated, the organic solvent is evaporated off and bake is preferably effected to promote crosslinking reaction in order to prevent intermixing with any overlying layer subsequently coated thereon. The bake is preferably at a temperature of 100 to 350° C. for a time of 10 to 300 seconds. While the thickness of the antireflective coating layer may be selected appropriate for enhancing the NIR absorbing effect, it preferably has a thickness of 10 to 200 nm, more preferably 20 to 150 nm.

The Si-containing layer of the multilayer film may be formed by coating and baking or CVD. When the layer is formed by the coating method, silsesquioxane or polyhedral oligomeric silsesquioxane (POSS) is used. In the case of CVD, various silane gases are used as the reactant. The Si-containing layer may have a light-absorptive anti-reflecting function and in this case, it may contain a light absorptive group such as phenyl or it may be a SiON layer. An organic layer may intervene between the Si-containing layer and the resist layer. In this embodiment, the organic layer may be an antireflective coating layer. Although the thickness of the Si-containing layer is not particularly limited, it preferably has a thickness of 10 to 100 nm, and more preferably 20 to 80 nm.

The multilayer film includes a photoresist layer which is formed on the NIR absorptive layer by coating a photoresist composition. The photoresist composition may be any of well-known photoresist compositions as described, for example, in JP-A H09-73173 and JP-A 2000-336121.

The resist layer may be formed by applying such a photoresist composition by any suitable coating techniques including spin coating, roll coating, flow coating, dip coating, spray coating, and doctor coating, and prebaking preferably on a hot plate at 50 to 150° C. for 1 to 10 minutes, more preferably at 60 to 140° C. for 1 to 5 minutes, thereby forming a layer of 0.01 to 2.0 μm thick.

In the event the immersion lithography using water is applied to the resist composition used herein, particularly in the absence of a resist protective layer, the resist composition may have added thereto a surfactant having a propensity to segregate at the resist surface after spin coating for achieving a function of minimizing water penetration or leaching. The preferred surfactant is a polymeric surfactant which is insoluble in water, but soluble in alkaline developer, and especially which is water repellent and enhances water slippage. Suitable polymeric surfactants are shown below.

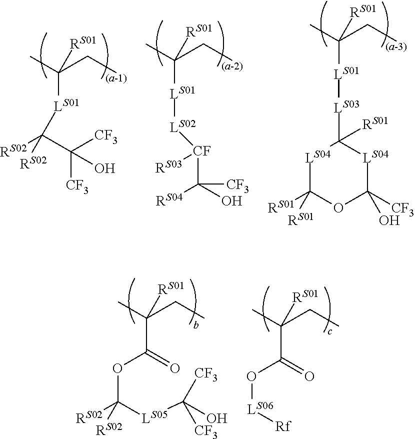

Herein L^{S01} is each independently —C(═O)—O—, —O—, or —C(═O)-L^{S07}-C(═O)—O— wherein L^{S07} is a straight, branched or cyclic C₁-C₁₀ alkylene group. R^{1a} is each independently hydrogen, fluorine, methyl or trifluoromethyl. R^{S02} is each independently hydrogen or a straight, branched or cyclic C₁-C₂₀ alkyl or fluoroalkyl group, or two R^{S02} in a common unit may bond together to form a ring with the carbon atom to which they are attached, and in this event, they together represent a straight, branched or cyclic C₂-C₂₀ alkylene or fluoroalkylene group. R^{S03} is fluorine or hydrogen, or R^{S03} may bond with L^{S02} in a common unit to form a C₃-C₁₀ non-aromatic ring with the carbon atom to which they are attached. L^{S02} is a straight, branched or cyclic C₁-C₆ alkylene group in which at least one hydrogen atom may be substituted by a fluorine atom. R^{S04} is a straight or branched C₁-C₁₀ alkyl group in which at least one hydrogen atom is substituted by a fluorine atom. Alternatively, L^{S02} and R^{S04} may bond together to form a non-aromatic ring with the carbon atoms to which they are attached, and in this event, the ring represents a trivalent organic group of 2 to 12 carbon atoms in total. L^{S03} is a single bond or a C₁-C₄ alkylene. L^{S04} is each independently a single bond, —O—, or —CR^{S01}R^{S01}—. L^{S05} is a straight or branched C₁-C₄ alkylene group, or may bond with R^{S02} within a common unit to form a C₃-C₁₀ non-aromatic ring with the carbon atom to which they are attached. L^{S06} is methylene, 1,2-ethylene, 1,3-propylene, or 1,4-butylene. Rf is a linear perfluoroalkyl group of 3 to 6 carbon atoms, typically 3H-perfluoropropyl, 4H-perfluorobutyl, 5H-perfluoropentyl, or 6H-perfluorohexyl. The subscripts (a-1), (a-2), (a-3), b and c are numbers in the range: 0≦(a-1)<1, 0≦(a-2)<1, 0≦(a-3)<1, 0<(a-1)+(a-2)+(a-3)<1, 0≦b<1, 0≦c<1, and 0<(a-1)+(a-2)+(a-3)+b+c≦1.

In the resist composition, the polymeric surfactant is preferably formulated in an amount of 0.001 to 20 parts, and more preferably 0.01 to 10 parts by weight, per 100 parts by weight of the base resin. Reference should also be made to JP-A 2007-297590.

The multilayer film may include a resist protective layer so that it may be applied to the immersion lithography using water. The protective layer prevents any component from being leached out of the resist layer, thereby improving the water slip on the layer surface. The protective layer may preferably be formed of a base resin which is insoluble in water, but soluble in alkaline developer, for example, a polymer having an alcohol structure having a plurality of fluorine atoms substituted at β-position such as a polymer having 1,1,1,3,3,3-hexafluoro-2-propanol residue. Typically a protective layer-forming composition comprising such a base resin in a higher alcohol of at least 4 carbon atoms or an ether compound of 8 to 12 carbon atoms is used. The protective layer may be formed by spin coating the protective layer-forming composition onto a resist layer as prebaked, and prebaking the coating. The protective layer preferably has a thickness of 10 to 200 nm.

### Example

Examples of the invention are given below by way of illustration and not by way of limitation. For all polymers, Mw and Mn are determined by GPC versus polystyrene standards. The amount “pbw” is parts by weight. MAIB is dimethyl 2,2′-azobisisobutyrate.

### Synthesis of Polymer 1

In a nitrogen atmosphere, a flask was charged with 11.26 g of 3,4-epoxycyclohexylmethyl methacrylate, 8.74 g of acenaphthylene, 0.793 g of MAIB, and 20.00 g of PGMEA to form a monomer solution 1. Another flask in a nitrogen atmosphere was charged with 10.00 g of PGMEA, and heated at 80° C. while stirring. Thereafter, monomer solution 1 was added dropwise to the other flask over 2 hours. The polymerization solution was continuously stirred for 6 hours while maintaining the temperature of 80° C. With the heat interrupted, the flask was allowed to cool down to room temperature. The polymerization solution was diluted with 30.00 g of PGMEA and added dropwise to 320 g of methanol being stirred, for precipitation. The polymer precipitate was collected by filtration, washed twice with 120 g of methanol, and vacuum dried at 50° C. for 20 hours, yielding 18.16 g of a polymer in white powder solid form, designated Polymer 1. The yield was 91%. Polymer 1 had a Mw of 12,300 and a dispersity Mw/Mn of 2.01. Upon ¹H-NMR analysis, Polymer 1 had a copolymer compositional ratio of 51/49 mol %, expressed as (units derived from 3,4-epoxycyclohexylmethyl methacrylate)/(units derived from acenaphthylene).

### Synthesis of Polymer 2

In a nitrogen atmosphere, a flask was charged with 9.25 g of 3,4-epoxycyclohexylmethyl methacrylate, 10.75 g of acenaphthylene, 0.814 g of MAIB, and 20.00 g of PGMEA to form a monomer solution 2. Another flask in a nitrogen atmosphere was charged with 10.00 g of PGMEA, and heated at 80° C. while stirring. Thereafter, monomer solution 2 was added dropwise to the other flask over 2 hours. The polymerization solution was continuously stirred for 6 hours while maintaining the temperature of 80° C. With the heat interrupted, the flask was allowed to cool down to room temperature. The polymerization solution was diluted with 30.00 g of PGMEA and added dropwise to 320 g of methanol being stirred, for precipitation. The polymer precipitate was collected by filtration, washed twice with 120 g of methanol, and vacuum dried at 50° C. for 20 hours, yielding 17.42 g of a polymer in white powder solid form, designated Polymer 2. The yield was 87%. Polymer 2 had a Mw of 10,800 and a dispersity Mw/Mn of 1.93. Upon ¹H-NMR analysis, Polymer 2 had a copolymer compositional ratio of 41/59 mol %, expressed as (units derived from 3,4-epoxycyclohexylmethyl methacrylate)/(units derived from acenaphthylene).

### Synthesis of Polymer 3

In a nitrogen atmosphere, a flask was charged with 7.12 g of 3,4-epoxycyclohexylmethyl methacrylate, 12.88 g of acenaphthylene, 0.835 g of MAIB, and 20.00 g of PGMEA to form a monomer solution 3. Another flask in a nitrogen atmosphere was charged with 10.00 g of PGMEA, and heated at 80° C. while stirring. Thereafter, monomer solution 3 was added dropwise to the other flask over 2 hours. The polymerization solution was continuously stirred for 6 hours while maintaining the temperature of 80° C. With the heat interrupted, the flask was allowed to cool down to room temperature. The polymerization solution was diluted with 30.00 g of PGMEA and added dropwise to 320 g of methanol being stirred, for precipitation. The polymer precipitate was collected by filtration, washed twice with 120 g of methanol, and vacuum dried at 50° C. for 20 hours, yielding 16.87 g of a polymer in white powder solid form, designated Polymer 3. The yield was 84%. Polymer 3 had a Mw of 10,100 and a dispersity Mw/Mn of 1.98. Upon ¹H-NMR analysis, Polymer 3 had a copolymer compositional ratio of 31/69 mol %, expressed as (units derived from 3,4-epoxycyclohexylmethyl methacrylate)/(units derived from acenaphthylene).

### Synthesis of Polymer 4

In a nitrogen atmosphere, a flask was charged with 11.92 g of 3,4-epoxycyclohexylmethyl methacrylate, 5.55 g of acenaphthylene, 2.53 g of styrene, 0.839 g of MAIB, and 20.00 g of PGMEA to form a monomer solution 4. Another flask in a nitrogen atmosphere was charged with 10.00 g of PGMEA, and heated at 80° C. while stirring. Thereafter, monomer solution 4 was added dropwise to the other flask over 2 hours. The polymerization solution was continuously stirred for 6 hours while maintaining the temperature of 80° C. With the heat interrupted, the flask was allowed to cool down to room temperature. The polymerization solution was diluted with 16.67 g of PGMEA and added dropwise to 320 g of methanol being stirred, for precipitation. The polymer precipitate was collected by filtration, washed twice with 120 g of methanol, and vacuum dried at 50° C. for 20 hours, yielding 17.13 g of a polymer in white powder solid form, designated Polymer 4. The yield was 86%. Polymer 4 had a Mw of 12,100 and a dispersity Mw/Mn of 2.19. Upon ¹H-NMR analysis, Polymer 4 had a copolymer compositional ratio of 48/31/21 mol %, expressed as (units derived from 3,4-epoxycyclohexylmethyl methacrylate)/(units derived from acenaphthylene)/(units derived from styrene).

Polymers 5 to 7 for comparative examples were synthesized through similar polymerization reaction.

### Synthesis of Polymer 5

In a nitrogen atmosphere, a flask was charged with 13.07 g of 3,4-epoxycyclohexylmethyl methacrylate, 6.93 g of styrene, 0.920 g of MAIB, and 20.00 g of PGMEA to form a monomer solution 5. Another flask in a nitrogen atmosphere was charged with 10.00 g of PGMEA, and heated at 80° C. while stirring. Thereafter, monomer solution 5 was added dropwise to the other flask over 2 hours. The polymerization solution was continuously stirred for 6 hours while maintaining the temperature of 80° C. With the heat interrupted, the flask was allowed to cool down to room temperature. The polymerization solution was diluted with 16.67 g of PGMEA and added dropwise to a mixture of 32 g of water and 288 g of methanol being stirred, for precipitation. The polymer precipitate was collected by filtration, washed twice with 120 g of methanol, and vacuum dried at 50° C. for 20 hours, yielding 18.07 g of a polymer in white powder solid form, designated Polymer 5. The yield was 90%. Polymer 5 had a Mw of 14,300 and a dispersity Mw/Mn of 2.73. Upon ¹H-NMR analysis, Polymer 5 had a copolymer compositional ratio of 52/48 mol %, expressed as (units derived from 3,4-epoxycyclohexylmethyl methacrylate)/(units derived from styrene).

### Synthesis of Polymer 6

In a nitrogen atmosphere, a flask was charged with 11.20 g of 3,4-epoxycyclohexylmethyl methacrylate, 8.80 g of 2-vinylnaphthalene, 0.788 g of MAIB, and 20.00 g of PGMEA to form a monomer solution 6. Another flask in a nitrogen atmosphere was charged with 10.00 g of PGMEA, and heated at 80° C. while stirring. Thereafter, monomer solution 6 was added dropwise to the other flask over 2 hours. The polymerization solution was continuously stirred for 2 hours while maintaining the temperature of 80° C. With the heat interrupted, the flask was allowed to cool down to room temperature. The polymerization solution was diluted with 16.67 g of PGMEA and added dropwise to a mixture of 32 g of water and 288 g of methanol being stirred, for precipitation. The polymer precipitate was collected by filtration, washed twice with 120 g of methanol, and vacuum dried at 50° C. for 20 hours, yielding 17.85 g of a polymer in white powder solid form, designated Polymer 6. The yield was 89%. Polymer 6 had a Mw of 13,700 and a dispersity Mw/Mn of 1.78. Upon ¹H-NMR analysis, Polymer 6 had a copolymer compositional ratio of 51/49 mol %, expressed as to (units derived from 3,4-epoxycyclohexylmethyl methacrylate)/(units derived from 2-vinylnaphthalene).

### Synthesis of Polymer 7

In a nitrogen atmosphere, a flask was charged with 20.00 g of 3,4-epoxycyclohexylmethyl methacrylate, 0.939 g of MAIB, and 35.00 g of PGMEA to form a monomer solution 7. Another flask in a nitrogen atmosphere was charged with 11.67 g of PGMEA, and heated at 80° C. while stirring. Thereafter, monomer solution 7 was added dropwise to the other flask over 4 hours. The polymerization solution was continuously stirred for 2 hours while maintaining the temperature of 80° C. With the heat interrupted, the flask was allowed to cool down to room temperature. The polymerization solution was diluted with 13.33 g of PGMEA and added dropwise to 200 g of n-hexane being stirred, for precipitation. The polymer precipitate was collected by filtration, washed twice with 120 g of n-hexane, and vacuum dried at 50° C. for 20 hours, yielding 18.88 g of a polymer in white powder solid form, designated Polymer 7. The yield was 94%. Polymer 7 had a Mw of 11,700 and a dispersity Mw/Mn of 2.49.

### NIR-Absorbing Dye D1

NIR-absorbing dye D1 is 3-butyl-2-(2-{3-[2-(3-butyl-1,1-dimethyl-1H-benzo[e]indol-2(3H)-ylidene)ethylidene]-2-(phenylsulfonyl)cyclohex-1-en-1-yl}ethenyl)-1,1-dimethyl-1H-benzo[e]indol-3-ium bis(trifluoromethylsulfonyl)imide which is commercially available. Its structure is shown below.

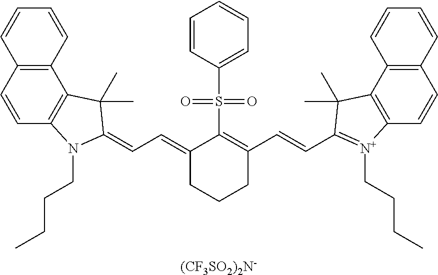

### Preparation of NIR-Absorbing Dye D2

NIR-absorbing dye D2 is 2-(2-{3-[(2-(3,3-dimethyl-1-(2-hydroxyethyl)-indol-2(3H)-ylidene)ethylidene]-2-chlorocyclopent-1-en-1-yl}ethenyl)-3,3-dimethyl-1-(2-hydroxyethyl)-(3H)-indol-1-ium bis(trifluoromethylsulfonyl)-imide. It was prepared by the following procedure.

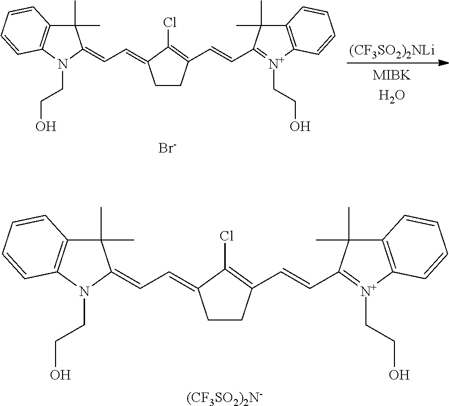

A mixture of 1.81 g (3 mmol) of 2-(2-[(3-[2-(3,3-dimethyl-1-(2-hydroxyethyl)-indol-2(3H)-ylidene)ethylidene]-2-chlorocyclopent-1-en-1-yl}ethenyl)-3,3-dimethyl-1-(2-hydroxyethyl)-(3H)-indol-1-ium bromide, 1.31 g (4.5 mmol) of lithium bis(trifluoromethanesulfonyl)imide, 40 g of water, and 40 g of methyl isobutyl ketone was stirred for 9 hours at room temperature, whereupon the organic layer was taken out. The organic layer was combined with 0.43 g (1.5 mmol) of lithium bis(trifluoromethanesulfonyl)imide and 20 g of water and stirred overnight, whereupon the organic layer was taken out. The organic layer was washed with water and concentrated in vacuum. Diisopropyl ether was added to the residue for recrystallization. The crystal was collected and dried in vacuum, obtaining the target compound, 2-(2-{3-[2-(3,3-dimethyl-1-(2-hydroxyethyl)-indol-2(3H)-ylidene)ethylidene]-2-chlorocyclopent-1-en-1-yl)ethenyl)-3,3-dimethyl-1-(2-hydroxyethyl)-(3H)-indol-1-ium bis(trifluoromethylsulfonyl)imide. Brown crystal, 2.2 g, yield 93%.

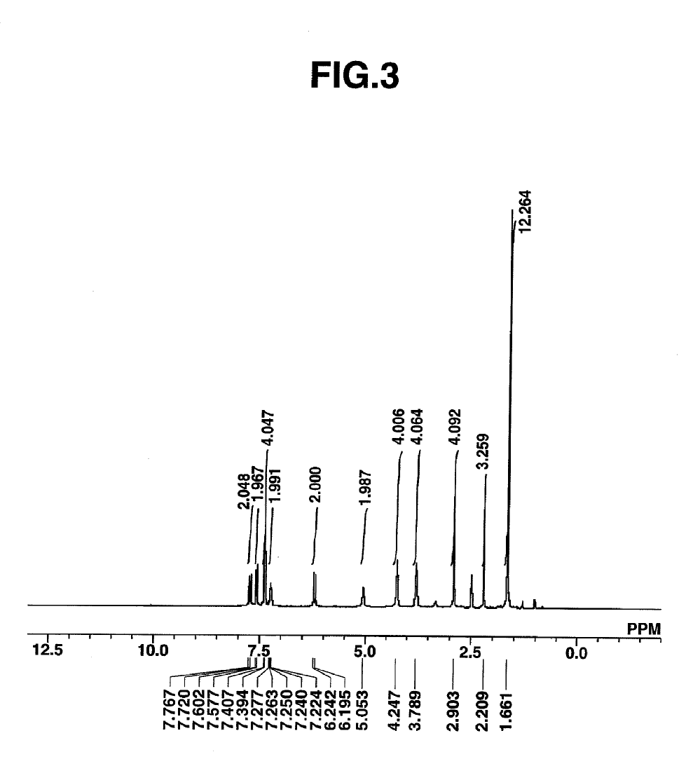

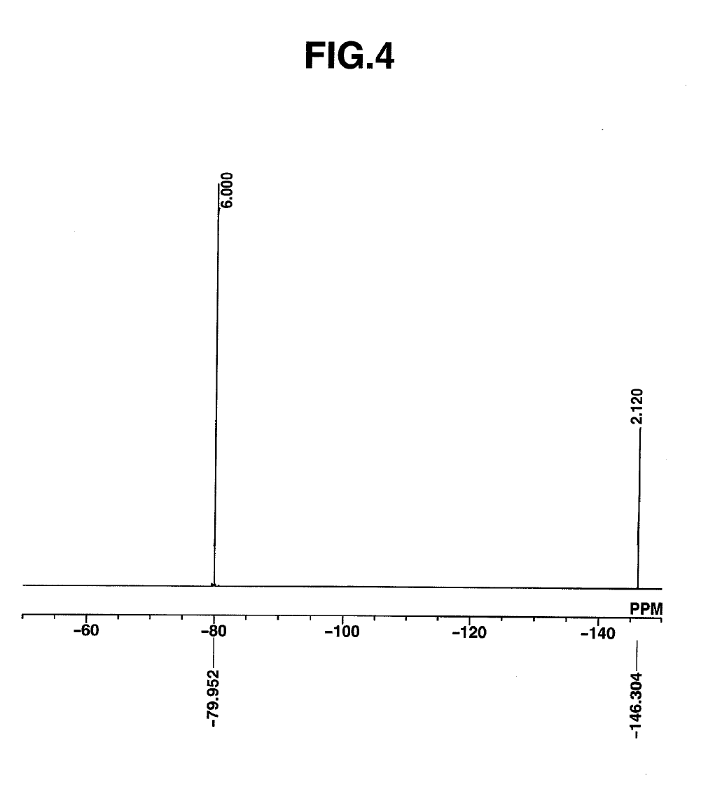

The compound was analyzed by attenuated total reflection infrared absorption and nuclear magnetic resonance spectroscopies. The spectral data are shown below. The NMR spectra (¹H-NMR and ¹⁹F-NMR/DMSO-d₆) are shown in FIGS. 3 and 4. It is noted that in ¹H-NMR analysis, traces of residual solvents (diisopropyl ether, methyl isobutyl ketone, water) were observed. From the data of ¹H-NMR and ¹⁹F-NMR spectroscopies using 1,2,4,5-tetrafluoro-3,6-dimethylbenzene as the internal standard, an anion/cation ratio was computed to be 1.00/0.97.

### Infrared Absorption Spectrum IR (D-ATR)

3526, 3413, 2932, 2883, 1552, 1500, 1452, 1434, 1387, 1362, 1337, 1308, 1276, 1252, 1205, 1132, 1111, 1088, 1050, 1029, 1012, 949, 915, 777, 750, 714, 665, 618 cm⁻¹

### Time-of-Flight Mass Spectroscopy (TOF-MS); MALDI

Positive M⁺529 (corresponding to C₃₃H₃₈ClN₂O₂)

Negative M⁻279 (corresponding to C₂F₆NO₄S₂)

### Preparation of NIR-Absorbing Dye D3

NIR-absorbing dye D3 is 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl}ethenyl)-1,1-dimethyl-1H-benzo[e]indol-3-ium perfluorobutanesulfonate. It was prepared by the following procedure.

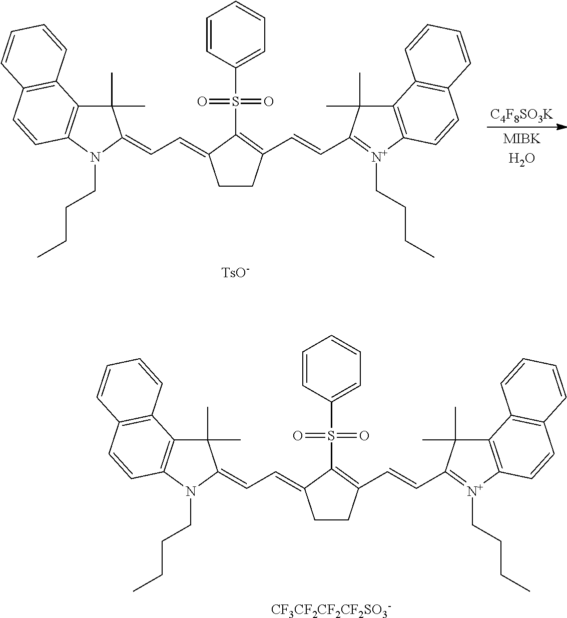

A mixture of 0.96 g (1 mmol) of 3-butyl-2-(2-[3-[2-(3-butyl-1,1-dimethyl-1H-benzo[e]indol-2(3H)-ylidene)-ethylidene]-2-(phenylsulfonyl)cyclopent-1-en-1-yl}ethenyl)-1,1-dimethyl-1H-benzo[e]indol-3-ium p-toluenesulfonate, 0.51 g (1.5 mmol) of potassium perfluorobutanesulfonate, 20 g of water, and 20 g of methyl isobutyl ketone was stirred for 6 hours at room temperature, whereupon the organic layer was taken out. The organic layer was combined with 0.17 g (0.5 mmol) of potassium perfluorobutanesulfonate and 20 g of water and stirred overnight, whereupon the organic layer was taken out. The organic layer was washed with water and concentrated in vacuum. Diisopropyl ether was added to the residue for recrystallization. The crystal was collected and dried in vacuum, obtaining the target compound, 3-butyl-2-(2-{3-[2-(3-butyl-1,1-dimethyl-1H-benzo[e]indol-2(3H)-ylidene)ethylidene)-2-(phenylsulfonyl)cyclopent-1-en-1-yl)ethenyl)-1,1-dimethyl-1H-benzo[e]indol-3-ium perfluorobutanesulfonate. Brown crystal, 1.1 g, yield 92%.

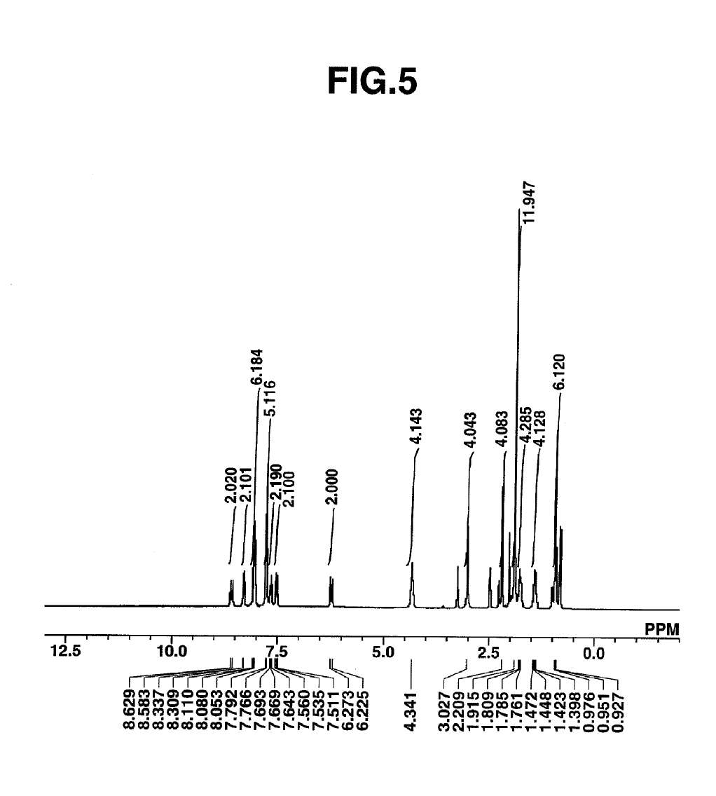

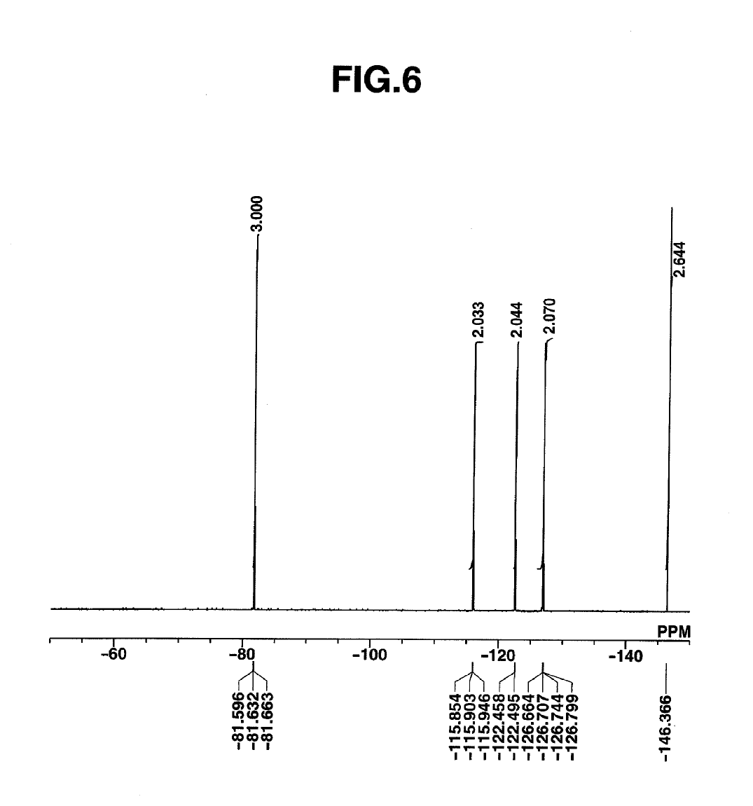

The compound was analyzed by infrared absorption and nuclear magnetic resonance spectroscopies. The spectral data are shown below. The NMR spectra (¹H-NMR and ¹⁹F-NMR/DMSO-d₆) are shown in FIGS. 5 and 6. It is noted that in ¹H-NMR analysis, traces of residual solvents (diisopropyl ether, methyl isobutyl ketone, water) were observed. From the data of ¹H-NMR and ¹⁹F-NMR spectroscopies using 1,2,4,5-tetrafluoro-3,6-dimethylbenzene as the internal standard, an anion/cation ratio was computed to be 1.00/0.98.

### Infrared Absorption Spectrum IR (D-ATR)

2958, 2932, 2870, 1712, 1541, 1505, 1440, 1430, 1409, 1392, 1359, 1322, 1272, 1229, 1187, 1170, 1140, 1127, 1109, 1083, 1053, 1047, 1014, 959, 927, 902, 892, 867, 834, 818, 805, 786, 754, 724, 682, 652, 634, 624, 602, 584 cm⁻¹

### Time-of-Flight Mass Spectroscopy (TOF-MS); MALDI

Positive M⁺759 (corresponding to C₅₁H₅₅N₂O₂S)

Negative M⁻298 (corresponding to C₄F₉O₃S)

### Preparation of NIR-Absorbing Dye D4

NIR-absorbing dye D4 is 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl}ethenyl)-1,1-dimethyl-1H-benzo[e]indol-3-ium bis(trifluoromethylsulfonyl)imide. It was prepared by the following procedure.

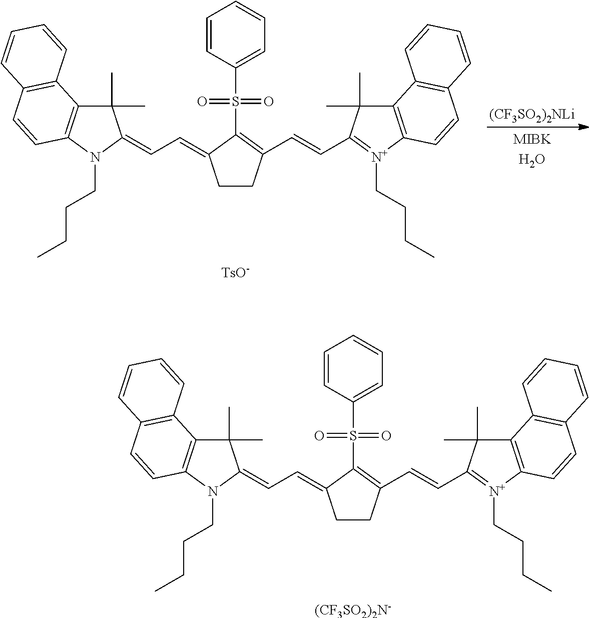

A mixture of 2.87 g (3 mmol) of 3-butyl-2-(2-(3-[2-(3-butyl-1,1-dimethyl-1H-benzo[e]indol-2(3H)-ylidene)ethylidene]-2-(phenylsulfonyl)cyclopent-1-en-1-yl)ethenyl)-1,1-dimethyl-1H-benzo[e]indol-3-ium p-toluenesulfonate, 1.31 g (4.5 mmol) of lithium bis(trifluoromethanesulfonyl)imide, 40 g of water, and 40 g of methyl isobutyl ketone was stirred for 8 hours at room temperature, whereupon the organic layer was taken out. The organic layer was combined with 0.43 g (1.5 mmol) of lithium bis(trifluoromethanesulfonyl)imide and 40 g of water and stirred overnight, whereupon the organic layer was taken out. The organic layer was washed with water and concentrated in vacuum. Diisopropyl ether was added to the residue for recrystallization. The crystal was collected and dried in vacuum, obtaining the target compound, 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl}ethenyl)-1,1-dimethyl-1H-benzo[e]indol-3-ium bis(trifluoromethylsulfonyl)imide. Brown crystal, 2.9 g, yield 87%.

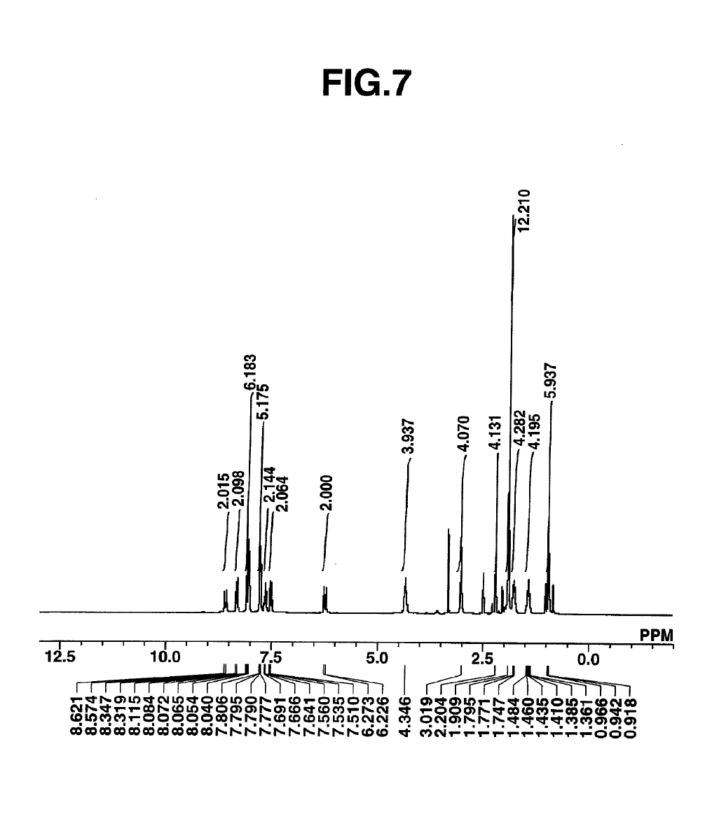

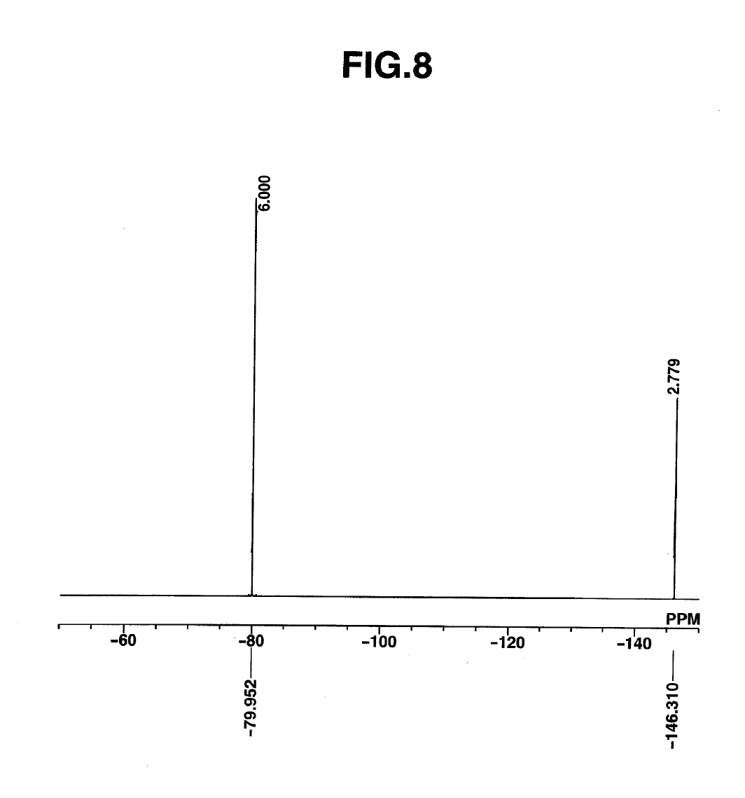

The compound was analyzed by infrared absorption and nuclear magnetic resonance spectroscopies. The spectral data are shown below. The NMR spectra (¹H-NMR and ¹⁹F-NMR/DMSO-d₆) are shown in FIGS. 7 and 8. It is noted that in ¹H-NMR analysis, traces of residual solvents (diisopropyl ether, methyl isobutyl ketone, water) were observed. From the data of ¹H-NMR and ¹⁹F-NMR spectroscopies using 1,2,4,5-tetrafluoro-3,6-dimethylbenzene as the internal standard, an anion/cation ratio was computed to be 1.00/0.99.

### Infrared Absorption Spectrum IR (KBR)

3432, 2961, 2933, 2873, 1624, 1599, 1584, 1536, 1503, 1460, 1441, 1432, 1416, 1387, 1352, 1280, 1228, 1182, 1166, 1137, 1102, 1061, 1013, 958, 922, 897, 864, 832, 808, 786, 748, 725, 680, 651, 616, 588, 569, 553, 534, 525, 511 cm⁻¹

### Time-of-Flight Mass Spectroscopy (TOF-MS); MALDI

Positive M⁺759 (corresponding to C₅₁H₅₅N₂O₂S)

Negative M⁻279 (corresponding to C₂F₆O₄NS₂)

### Preparation of NIR-Absorbing Dye D5

NIR-absorbing dye D5 is 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl)ethenyl)-1,1-dimethyl-1H-benzo[e]indol-3-ium tris(trifluoromethylsulfonyl)methide. It was prepared by the following procedure.

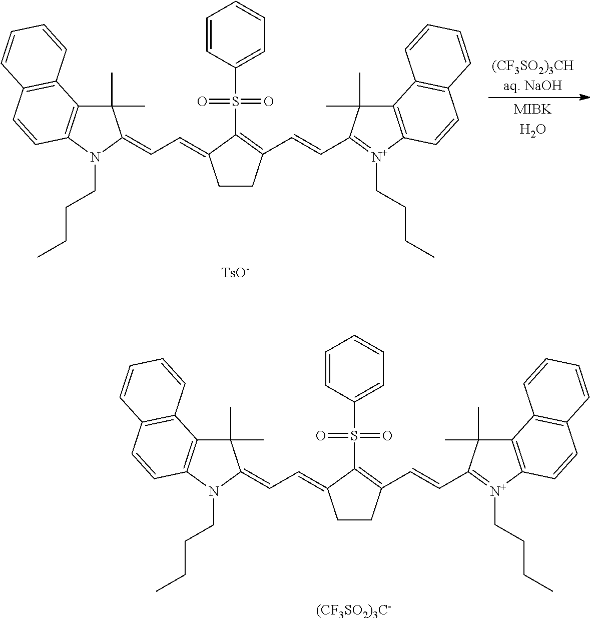

A mixture of 1.86 g (2 mmol) of 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl}ethenyl)-1,1-dimethyl-1H-benzo[e]indol-3-ium p-toluenesulfonate, 2.21 g (3 mmol) of a 56% tris(trifluoromethanesulfonyl)methide acid aqueous solution, 0.48 g of a 25% sodium hydroxide aqueous solution, 30 g of water, and 30 g of methyl isobutyl ketone was stirred for 8 hours at room temperature, whereupon the organic layer was taken out. The organic layer was combined with 0.74 g (1 mmol) of a 56% tris(trifluoromethanesulfonyl)methide acid aqueous solution and 30 g of water and stirred overnight, whereupon the organic layer was taken out. The organic layer was washed with water and concentrated in vacuum. Diisopropyl ether was added to the residue for recrystallization. The crystal was collected and dried in vacuum, obtaining the target compound, 3-butyl-2-(2-[(3-[2-(3-butyl-1,1-dimethyl-1H-benzo[e]indol-2(3H)-ylidene)ethylidene]-2-(phenylsulfonyl)-cyclopent-1-en-1-yl)ethenyl)-1,1-dimethyl-1H-benzo[e]indol-3-ium tris(trifluoromethylsulfonyl)methide. Brown crystal, 2.2 g, yield 92%.

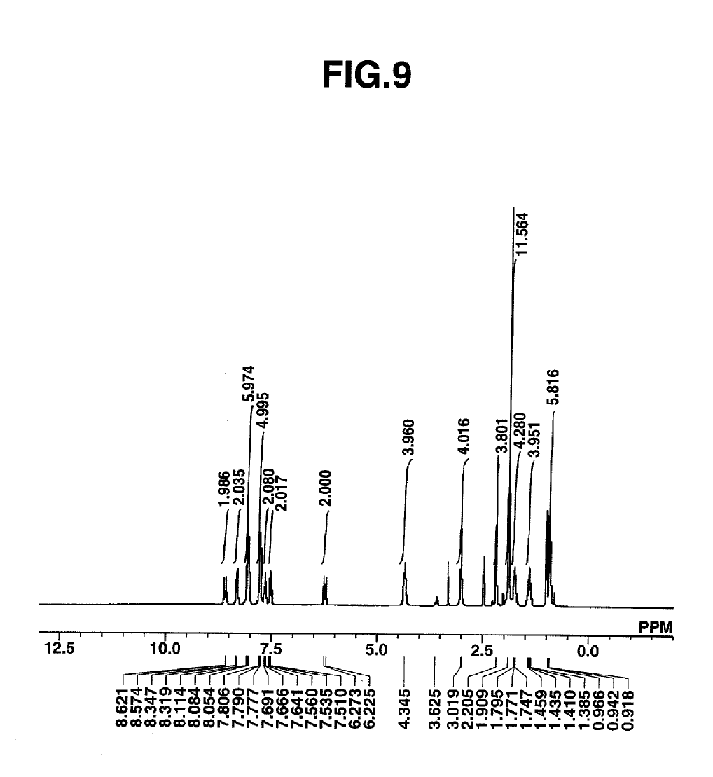

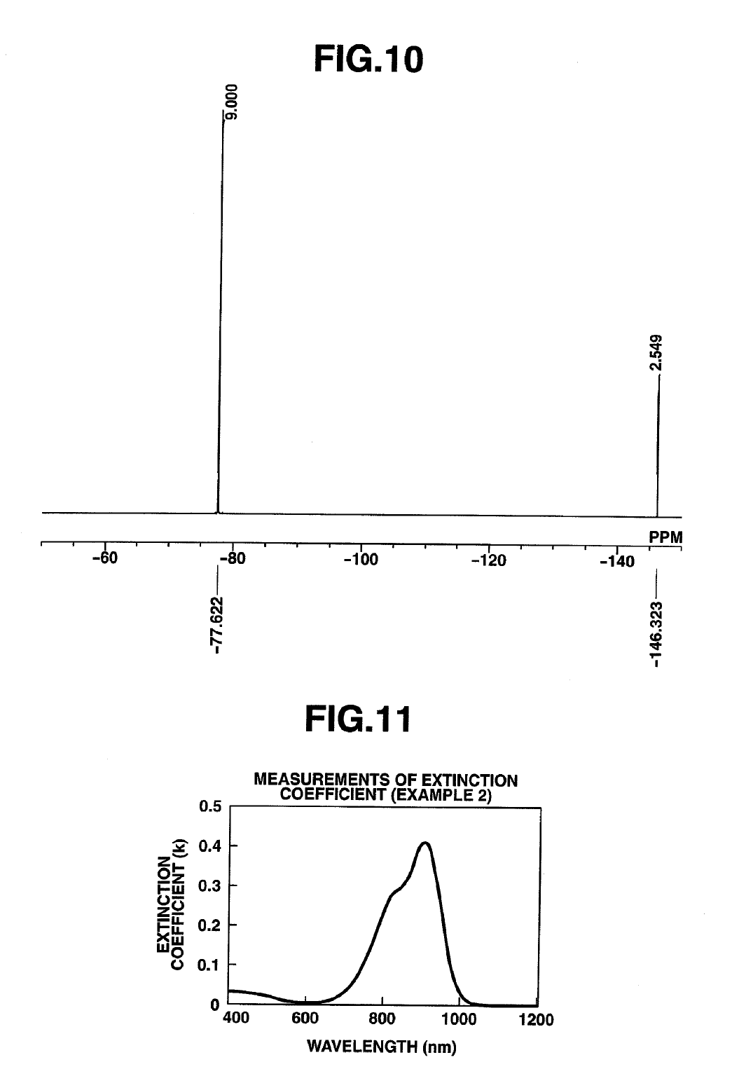

The compound was analyzed by infrared and nuclear magnetic resonance spectroscopies. The spectral data are shown below. The NMR spectra (¹H-NMR and ¹⁹F-NMR/DMSO-d₆) are shown in FIGS. 9 and 10. It is noted that in ¹H-NMR analysis, traces of residual solvents (diisopropyl ether, methyl isobutyl ketone, water) were observed. From the data of ¹H-NMR and ¹⁹F-NMR spectroscopies using 1,2,4,5-tetrafluoro-3,6-dimethylbenzene as the internal standard, an anion/cation ratio was computed to be 1.00/0.99.

### Infrared Absorption Spectrum IR (D-ATR)

2962, 2934, 1538, 1504, 1463, 1442, 1433, 1418, 1377, 1356, 1325, 1275, 1234, 1181, 1140, 1123, 1084, 1013, 974, 926, 897, 868, 833, 805, 786, 751, 724, 682, 622, 584 cm⁻¹

### Time-of-Flight Mass Spectroscopy (TOF-MS); MALDI

Positive M⁺759 (corresponding to C₅₁H₅₅N₂O₂S)

Negative M⁻410 (corresponding to C₄F₉O₆S₃)

### Computation of Reflectivity of ArF Excimer Laser

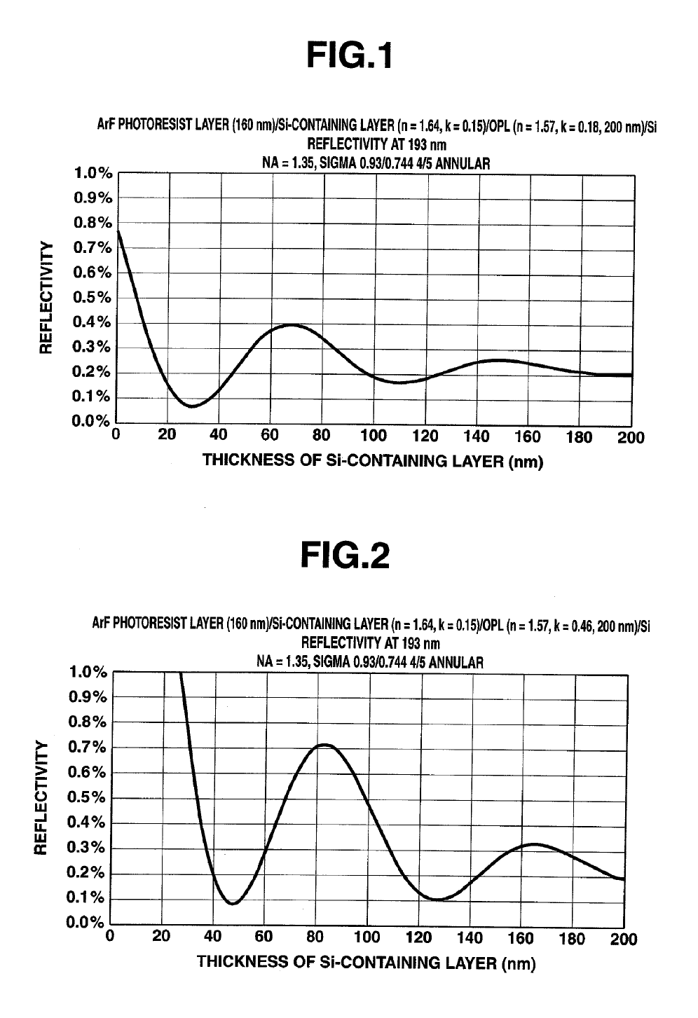

A multilayer film consisting of ArF photoresist layer/silicon-containing layer/OPL was formed on a silicon wafer. For this structure, a reflectivity of ArF excimer laser was computed. Under the conditions that NA=1.35, the ArF photoresist layer has a thickness of 160 nm, a refractive index n of 1.67, and an extinction coefficient k of 0.04, the Si-containing layer has a refractive index n of 1.64 and an extinction coefficient k of 0.15, and the OPL based on Polymer 1 has a thickness of 200 nm, a refractive index n of 1.57, and an extinction coefficient k of 0.18, FIG. 1 is a diagram showing a change of reflectivity with the varying thickness of the Si-containing layer. Under the conditions that NA=1.35, the ArF photoresist layer has a thickness of 160 nm, a refractive index n of 1.67, and an extinction coefficient k of 0.04, the Si-containing layer has a refractive index n of 1.64 and an extinction coefficient k of 0.15, and the OPL based on Polymer 5 has a thickness of 200 nm, a refractive index n of 1.57, and an extinction coefficient k of 0.46, FIG. 2 is a diagram showing a change of reflectivity with the varying thickness of the Si-containing layer.

The optical constants of the ArF photoresist layer are values of a resist layer formed of a resist material based on the polymer identified below.

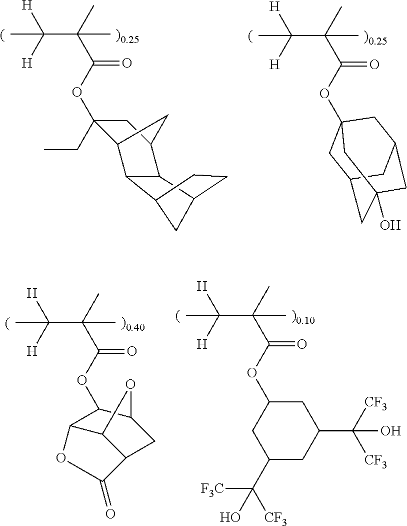

The optical constants of the Si-containing layer are values of a Si-containing layer formed of a Si-containing layer-forming material based on the polymer identified below.

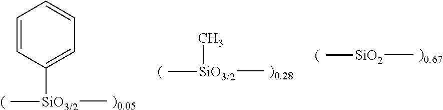

### Measurement of Optical Constants of Polymers

Each of Polymers 1 to 7 was mixed with a solvent according to the formulation shown in Table 1, obtaining Compositions 1 to 7. Each composition was filtered through a Teflone® filter with a pore size of 0.2 μm. The resulting coating solution was applied onto a silicon substrate and baked at 100° C. for 60 seconds to form a coating film for optical constant measurement. Using a variable angle spectroscopic ellipsometer (VASE®, by J. A. Woollam, Inc.), the optical constants (refractive index n and extinction coefficient k) of the film was measured at wavelength 193 nm. The results are also shown in Table 1.

TABLE 1

| | | Organic | Refractive | Extinction |
|---|---|---|---|---|
| | Polymer | solvent | index | coefficient |
| | (pbw) | (pbw) | n | k |
| Composition 1 | Polymer 1 | cyclohexanone | 1.59 | 0.11 |
| | (100) | (1,470) | | |
| Composition 2 | Polymer 2 | cyclohexanone | 1.56 | 0.15 |
| | (100) | (1,470) | | |
| Composition 3 | Polymer 3 | cyclohexanone | 1.53 | 0.19 |
| | (100) | (1,470) | | |
| Composition 4 | Polymer 4 | cyclohexanone | 1.64 | 0.26 |
| | (100) | (1,470) | | |
| Composition 5 | Polymer 5 | cyclohexanone | 1.71 | 0.51 |
| | (100) | (1,470) | | |
| Composition 6 | Polymer 6 | cyclohexanone | 1.50 | 0.09 |
| | (100) | (1,470) | | |
| Composition 7 | Polymer 7 | cyclohexanone | 1.70 | 0.01 |
| | (100) | (1,470) | | |

### Examples 1 to 4 & Comparative Examples 1 and 2

### Measurement of Optical Constants of NIR-Absorptive Layer

Each of Polymers 1 to 5 was mixed with NIR-absorbing dye D1, an acid generator (AG1), a surfactant FC-4430 (3M Sumitomo Co., Ltd.), and a solvent in accordance with the formulation shown in Table 2. Each composition was filtered through a Teflon® filter with a pore size of 0.2 μm. The resulting coating solution (Examples 1 to 4 and Comparative Examples 1 to 2) was applied onto a silicon substrate and baked at 195° C. for 60 seconds to form a coating film for optical constant measurement. Using a variable angle spectroscopic ellipsometer (VASE®, by J. A. Woollam, Inc.), the optical constants (refractive index n and extinction coefficient k) of the film was measured at wavelength 193 nm, as well as an extinction coefficient k at 920 nm, the peak absorption wavelength in the wavelength range of 400 to 1,200 nm in Examples 1 to 4 and Comparative Example 1. The results are also shown in Table 2.

TABLE 2

| | | NIR- | | | | 193 nm | | 920 nm |
|---|---|---|---|---|---|---|---|---|
| | | absorbing | Acid | | Organic | Refractive | Extinction | Extinction |
| | Polymer | dye | generator | Surfactant | solvent | index | coefficient | coefficient |
| | (pbw) | (pbw) | (pbw) | (pbw) | (pbw) | n | k | k |
| Example 1 | Polymer 1 | D1 | AG1 | FC-4430 | cyclohexanone | 1.57 | 0.18 | 0.40 |
| | (67) | (33) | (5) | (0.1) | (1,470) | | | |
| | | | | | PGMEA | | | |
| | | | | | (150) | | | |
| Example 2 | Polymer 2 | D1 | AG1 | FC-4430 | cyclohexanone | 1.54 | 0.20 | 0.39 |
| | (67) | (33) | (5) | (0.1) | (1,470) | | | |
| | | | | | PGMEA | | | |
| | | | | | (150) | | | |
| Example 3 | Polymer 3 | D1 | AG1 | FC-4430 | cyclohexanone | 1.53 | 0.23 | 0.39 |
| | (67) | (33) | (5) | (0.1) | (1,470) | | | |
| | | | | | PGMEA | | | |
| | | | | | (150) | | | |
| Example 4 | Polymer 4 | D1 | AG1 | FC-4430 | cyclohexanone | 1.60 | 0.29 | 0.40 |
| | (67) | (33) | (5) | (0.1) | (1,470) | | | |
| | | | | | PGMEA | | | |
| | | | | | (150) | | | |
| Comparative | Polymer 5 | D1 | AG1 | FC-4430 | cyclohexanone | 1.57 | 0.46 | 0.34 |
| Example 1 | (67) | (33) | (5) | (0.1) | (1,470) | | | |
| | | | | | PGMEA | | | |
| | | | | | (150) | | | |
| Comparative | Polymer 1 | — | AG1 | FC-4430 | cyclohexanone | 1.59 | 0.11 | 0.00 |
| Example 2 | (100) | | (5) | (0.1) | (1,470) | | | |
| | | | | | PGMEA | | | |
| | | | | | (150) | | | |

Note that the components in Table 2 are as identified below.
NIR-absorbing dye D1: 3-butyl-2-(2-{3-[2-(3-butyl-1,1-dimethyl-1H-benzo[e]indol-2(3H)-ylidene)ethylidene]-2-(phenylsulfonyl)cyclohex-1-en-1-yl}ethenyl)-1,1-dimethyl-1H-benzo[e]indol-3-ium bis(trifluoromethylsulfonyl)imide
Acid generator AG1: triethylammonium perfluorobutane-sulfonate

FIG. 11 is a diagram showing measured data of extinction coefficient of the layer of Example 2 over a wavelength range of 400 to 1,200 nm, demonstrating formation of a NIR-absorptive layer having the desired broad band of absorption in the NIR region. The NIR-absorptive layer of Comparative Example 1 had a refractive index of 1.57 and an extinction coefficient of 0.46 at 193 nm, and was inferior in antireflection effect to the NIR-absorptive layer of Example 1, as seen from the results of computation of reflectivity (see FIGS. 1 and 2).

### Examples 5 to 7 & Comparative Examples 3 and 4

### Evaluation of Solvent Resistance

Polymer 1, 5 or 6 was mixed with NIR-absorbing dye D1 or D2, an acid generator (AG1), a crosslinker (CR1), a surfactant FC-4430 (3M Sumitomo Co., Ltd.), and a solvent in accordance with the formulation shown in Table 3. Each composition was filtered through a Teflon® filter with a pore size of 0.2 μm. The resulting coating solution (Examples 5 to 7 and Comparative Examples 3 to 4) was applied onto a silicon substrate and baked at 195° C. for 60 seconds to form a NIR-absorptive film. A mixture of PGMEA and PGME (propylene glycol monomethyl ether) in a weight ratio of 30:70 was spin coated onto the film, followed by baking at 100° C. for 30 seconds. A difference in film thickness before and after solvent treatment was determined. The results are also shown in Table 3.

TABLE 3

| | | | | | | | Difference in |
|---|---|---|---|---|---|---|---|
| | | NIR- | | | | | film thickness |
| | | absorbing | Acid | | | Organic | by solvent |
| | Polymer | dye | generator | Crosslinker | Surfactant | solvent | treatment |
| | (pbw) | (pbw) | (pbw) | (pbw) | (pbw) | (pbw) | (nm) |
| Example 5 | Polymer 1 | D1 | AG1 | — | FC-4430 | cyclohexanone | −6.4 |
| | (67) | (33) | (5) | | (0.1) | (1,340) | |
| | | | | | | PGMEA | |
| | | | | | | (150) | |
| Example 6 | Polymer 1 | D2 | AG1 | — | FC-4430 | cyclohexanone | −6.2 |
| | (50) | (50) | (5) | | (0.1) | (1,340) | |
| | | | | | | PGMEA | |
| | | | | | | (150) | |
| Example 7 | Polymer 1 | D2 | AG1 | CR1 | FC-4430 | cyclohexanone | −1.0 |
| | (50) | (50) | (5) | (10.6) | (0.1) | (1,340) | |
| | | | | | | PGMEA | |
| | | | | | | (150) | |
| Comparative | Polymer 5 | D1 | AG1 | — | FC-4430 | cyclohexanone | −8.5 |
| Example 3 | (67) | (33) | (5) | | (0.1) | (1,340) | |
| | | | | | | PGMEA | |
| | | | | | | (150) | |
| Comparative | Polymer 6 | D1 | AG1 | | FC-4430 | cyclohexanone | −14.9 |
| Example 4 | (67) | (33) | (5) | — | (0.1) | (1,340) | |
| | | | | | | PGMEA | |
| | | | | | | (150) | |

Note that the components in Table 3 are as identified below.
NIR-absorbing dye D1: 3-butyl-2-(2-{3-[2-(3-butyl-1,1-dimethyl-1H-benzo[e]indol-2(3H)-ylidene)ethylidene]-2-(phenylsulfonyl)cyclohex-1-en-1-yl}ethenyl)-1,1-dimethyl-1H-benzo[e]indol-3-ium bis(trifluoromethylsulfonyl)imide
NIR-absorbing dye D2: 2-(2-{3-[2-(3,3-dimethyl-1-(2-hydroxyethyl)-indol-2(3H)-ylidene)ethylidene]-2-chlorocyclopent-1-en-1-yl}ethenyl)-3,3-dimethyl-1-(2-hydroxyethyl)-(3H)-indol-1-ium bis(trifluoromethylsulfonyl) imide
Acid generator AG1: triethylammonium perfluorobutanesulfonate
Crosslinker CR1: tetramethoxymethyl glycoluril

It is seen from Table 3 that the NIR-absorptive layers formed from the NIR-absorptive layer-forming compositions within the scope of the invention experienced a thickness reduction following solvent treatment which was smaller than that of the layers of Comparative Examples 3 and 4. High solvent resistance was achieved using Polymer 1. Crosslinker CR1 was effective for further improving the solvent resistance of layers.

### Examples 8 to 11 & Comparative Examples 5 to 7

### Evaluation of Dry Etch Resistance

Each of Polymers 1 to 5 and 7 was mixed with NIR-absorbing dye D1 or D3, an acid generator (AG1), a surfactant FC-4430 (3M Sumitomo Co., Ltd.), and a solvent in accordance with the formulation shown in Table 4. Each composition was filtered through a Teflon® filter with a pore size of 0.2 μm. The resulting coating solution (Examples 8 to 11 and Comparative Examples 5 to 7) was applied onto a silicon substrate and baked at 195° C. for 60 seconds in Examples 8 to 11 and Comparative Example 5, or at 185° C. for 60 seconds in Comparative Examples 6 and 7 to form a film for dry etching test.

Using a dry etching apparatus TE-8500P (Tokyo Electron Ltd.), the film was etched with CHF₃/CF₄ gas under the following conditions.

| | | |
|---|---|---|
| Chamber pressure | 300 | mTorr |
| RF power | 1000 | W |
| Gap | 9 | mm |
| CHF₃ gas flow rate | 50 | mL/min |
| CF₄ gas flow rate | 50 | mL/min |
| He gas flow rate | 200 | mL/min |
| O₂ gas flow rate | 7 | mL/min |
| Time | 60 | sec |

A difference in film thickness before and after etching was determined. The results are also shown in Table 4.

TABLE 4

| | | | | | | Difference in |
|---|---|---|---|---|---|---|
| | | NIR- | | | | film thickness |
| | | absorbing | Acid | | Organic | by CHF₃/CF₄ |
| | Polymer | dye | generator | Surfactant | solvent | gas etching |
| | (pbw) | (pbw) | (pbw) | (pbw) | (pbw) | (nm) |
| Example 8 | Polymer 1 | D1 | AG1 | FC-4430 | cyclohexanone | 106 |
| | (67) | (33) | (5) | (0.1) | (1,340) | |
| | | | | | PGMEA | |
| | | | | | (150) | |
| Example 9 | Polymer 2 | D1 | AG1 | FC-4430 | cyclohexanone | 102 |
| | (67) | (33) | (5) | (0.1) | (1,340) | |
| | | | | | PGMEA | |
| | | | | | (150) | |
| Example 10 | Polymer 3 | D1 | AG1 | FC-4430 | cyclohexanone | 98 |
| | (67) | (33) | (5) | (0.1) | (1,340) | |
| | | | | | PGMEA | |
| | | | | | (150) | |
| Example 11 | Polymer 4 | D1 | AG1 | FC-4430 | cyclohexanone | 109 |
| | (67) | (33) | (5) | (0.1) | (1,340) | |
| | | | | | PGMEA | |
| | | | | | (150) | |
| Comparative | Polymer 5 | D1 | AG1 | FC-4430 | cyclohexanone | 115 |
| Example 5 | (67) | (33) | (5) | (0.1) | (1,340) | |
| | | | | | PGMEA | |
| | | | | | (150) | |
| Comparative | Polymer 5 | D3 | AG1 | FC-4430 | cyclohexanone | 125 |
| Example 6 | (50) | (50) | (5) | (0.1) | (1,340) | |
| | | | | | PGMEA | |
| | | | | | (150) | |
| Comparative | Polymer 7 | D3 | AG1 | FC-4430 | cyclohexanone | 135 |
| Example 7 | (50) | (50) | (5) | (0.1) | (1,340) | |
| | | | | | PGMEA | |
| | | | | | (150) | |

Note that the components in Table 3 are as identified below.
NIR-absorbing dye D1: 3-butyl-2-(2-{3-[2-(3-butyl-1,1-dimethyl-1H-benzo[e]indol-2(3H)-ylidene)ethylidene]-2-(phenylsulfonyl)cyclohex-1-en-1-yl}ethenyl)-1,1-dimethyl-1H-benzo[e]indol-3-ium bis(trifluoromethylsulfonyl)imide
NIR-absorbing dye D3: 3-butyl-2-(2-{3-[2-(3-butyl-1,1-dimethyl-1H-benzo[e]indol-2(3H)-ylidene)ethylidene]-2-(phenylsulfonyl)cyclopent-1-en-1-yl}ethenyl)-1,1-dimethyl-1H-benzo[e]indol-3-ium perfluorobutanesulfonate
Acid generator AG1:triethylammonium perfluorobutane-sulfonate

It is seen from Table 4 that the NIR-absorptive layers formed from the NIR-absorptive layer-forming compositions within the scope of the invention had higher etch resistance than the layers of Comparative Examples 5 to 7.

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application Nos. 2010-098453 and 2011-047254 are incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A near-infrared absorptive layer-forming composition comprising
(A) at least one polymer comprising repeat units having the general formula (1): 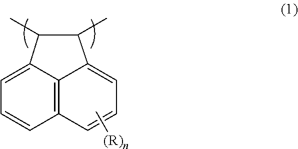
wherein R is hydrogen, a hydroxyl, carboxyl, hydroxymethyl, C₁-C₁₀ alkoxy, C₁-C₁₀ alkoxycarbonyl or C₁-C₁₀ acyloxy group, or a straight, branched or cyclic C₁-C₁₀ monovalent hydrocarbon group in which some hydrogen atoms may be substituted by halogen atoms and in which a —CH₂— moiety may be replaced by —O— or —C(═O)—, and n is an integer of 1 to 5,
(B) at least one near-infrared absorbing dye, and
(C) at least one solvent.

2. The composition of claim 1 wherein the polymer (A) comprises repeat units capable of undergoing crosslinking reaction in the presence of an acid.

3. The composition of claim 2 wherein the repeat units capable of undergoing crosslinking reaction in the presence of an acid have an oxirane structure and/or oxetane structure.

4. The composition of claim 1 wherein the near-infrared absorbing dye (B) comprises at least one cyanine dye capable of absorbing radiation in a wavelength range of 500 to 1,200 nm.

5. The composition of claim 1, further comprising at least one component selected from an acid generator, a crosslinker, and a surfactant.

6. A multilayer film comprising
a near-infrared absorptive layer which is formed by coating the near-infrared absorptive layer-forming composition of claim 1, and
a photoresist layer which is formed on the near-infrared absorptive layer by coating a photoresist composition.

7. The multilayer film of claim 6, further comprising a silicon-containing layer disposed beneath the photoresist layer, the near-infrared absorptive layer being disposed beneath the silicon-containing layer.

8. The multilayer film of claim 6 wherein the near-infrared absorptive layer functions as a layer for absorbing near-infrared radiation used in optical auto-focusing.

9. The multilayer film of claim 6 wherein the near-infrared absorptive layer functions as an antireflective coating for preventing reflection of exposure radiation used in resist pattern formation.
